(19) United States
(12) Patent Application Publication
(10) Pub. No.: US 2026/0147037 A1
(43) Pub. Date: May 28, 2026

(54) RECEPTION SIGNAL QUALITY MONITOR

(71) Applicant: THINE ELECTRONICS, INC., Tokyo (JP)

(72) Inventors: Tomohiro ISHIDA, Chiyoda-ku, Tokyo (JP); Shunichi KUBO, Chiyoda-ku, Tokyo (JP)

(73) Assignee: THINE ELECTRONICS, INC., Tokyo (JP)

(21) Appl. No.: 19/121,289

(22) PCT Filed: Oct. 11, 2023
(86) PCT No.: PCT/JP2023/036921

§ 371 Date: Apr. 15, 2025

(30) Foreign Application Priority Data
Oct. 17, 2022 (JP) 2022-166166

(51) Int. Cl. G01R 31/317

(52) U.S. Cl. CPC G01R 31/31703; G01R 31/31726

(57) ABSTRACT

The phase adjustment circuit 11 of this receiving signal quality monitor can sweep the phase of the sampling clock signal φe of the reference sampler within a phase range of several times the unit interval (UI) of the serial data signal. The first synchronization circuit 13A receives the first output signal of one sampler in the plurality of data reception samplers and the second output signal of the reference sampler SMe. The comparison logic circuit 15 receives the first and second output signals synchronously output from the first synchronization circuit 13A and outputs a comparison result related to the quality of the received signal.

### TECHNICAL FIELD

The present invention relates to a receiving signal quality monitor.

### BACKGROUND ART

Patent Literature 1, Patent Literature 2, Patent Literature 3, Non-Patent Literature 1, and Non-Patent Literature 2 disclose receiving devices. By incorporating a receiving signal quality monitor capable of outputting data (quality monitor signal of the received signal) for generating an eye diagram within the receiving device, the quality of the received signal can be evaluated by assessing this data.

### CITATION LIST

### Patent Literature

[Patent Literature 1] JP 2018-152731 A

[Patent Literature 2] U.S. Pat. No. 10,720,910

[Patent Literature 3] U.S. Pat. No. 10,735,116 Non-Patent Literature

[Non-Patent Literature 1] Yu-Chuan Lin, H. Tsao, “A 10-Gb/s Eye-Opening Monitor Circuit for Receiver Equalizer Adaptations in 65-nm CMOS”, IEEE Transactions on Very Large Scale Integration (VLSI) Systems, Jan. 1, 2020

[Non-Patent Literature 2] Hyosup Won, Joon-Yeong Lee, et al., “A 28-Gb/s Receiver With Self-contained Adaptive Equalization and Sampling Point Control Using Stochastic Sigma-Tracking Eye-Opening Monitor”, IEEE Transactions on Circuits and Systems I, Regular Papers, Volume 64, Issue 3, March 2017

### SUMMARY OF INVENTION

### Technical Problem

There is a demand for a receiving signal quality monitor that can accurately monitor the quality of the received signal while reducing circuit area and power consumption.

### Solution to Problem

The present receiving signal quality monitor includes: a plurality of data reception samplers, which are connected in parallel, each receiving a serial data signal and each being input with a sampling clock signal, resulting in multi-phase sampling clock signals being input to the data reception samplers; a reference sampler that receives the serial data signal; a phase adjustment circuit configured to allow the phase of the sampling clock signal input to the reference sampler to be swept within a phase range corresponding to N times a unit interval (UI) of the serial data signal, where 2≤N; a first synchronization circuit to which an output signal of one of the plurality of data reception samplers and an output signal of the reference sampler are input; and a comparison logic circuit to which two output signals synchronously output from the first synchronization circuit are input.

When the phase sweep range of the phase adjustment circuit is narrow, a delay adjustment circuit may be placed preceding the plurality of data reception samplers to counteract errors. In this device, since the phase sweep range is wide, the error-prone region can be sufficiently separated from the eye diagram formation region, allowing the omission of such circuits, thereby reducing circuit area and power consumption while accurately monitoring the quality of the received signal.

In the receiving signal quality monitor, it is preferable that a phase range adjusted by the phase adjustment circuit is at least one cycle of the sampling clock signal input to the reference sampler. By expanding the phase range, it becomes easier to capture the eye opening position even if it moves.

It is preferable that the receiving signal quality monitor further includes a counter that counts the output result of the comparison logic circuit.

The reference sampler preferably includes a first input terminal that receives the serial data signal and a second input terminal that receives a variable reference threshold voltage, and samples the comparison result between the serial data signal and the reference threshold voltage in synchronization with the sampling clock signal whose phase can be swept.

Each sampler included in the data reception samplers preferably includes: a first input terminal that receives the serial data signal; and a second input terminal that receives a threshold voltage, and wherein each sampler included in the data reception samplers is configured to sample, in synchronization with a sampling clock signal corresponding to the sampler, included in the multi-phase sampling clock signal, a comparison result between the serial data signal and the threshold voltage.

The receiving signal quality monitor preferably includes a second synchronization circuit that receives a plurality of output signals output from the plurality of data reception samplers; and a CDR (Clock and Data Recovery) circuit that receives the plurality of output signals output from the second synchronization circuit and generates the multi-phase sampling clock signal.

In the receiving signal quality monitor, the serial data signal is preferably a pulse amplitude modulation (PAM) signal having k levels, where k is an integer and satisfies 3≤k, and each of the plurality of data reception samplers comprises (k−1) samplers, each of which, along with the serial data signal, receives a threshold voltage at a different level, so that (k−1) comparison results are output from the (k−1) samplers.

In the receiving signal quality monitor, it is preferable that (k−1) comparison results are output from one sampler included in the plurality of data reception samplers, the (k−1) comparison results and an output signal of the reference sampler are input to the first synchronization circuit, the comparison logic circuit comprises (k−1) sub-comparison logic circuits, and each of the (k−1) sub-comparison logic circuits receives an output signal synchronously output from the first synchronization circuit. It receives at least two output signals synchronously output from the first synchronization circuit.

The phase adjustment circuit preferably includes a selection circuit to which the multi-phase sampling clock signal output from the CDR circuit is input, and a phase interpolator that receives the output signal of the selection circuit.

### Advantageous Effects of Invention

According to the receiving signal quality monitor, it is possible to accurately monitor the quality of the received signal while reducing circuit area and power consumption.

### BRIEF DESCRIPTION OF DRAWING

FIG. 1 is a block diagram showing a transmitting and receiving system and an external device 300.

FIG. 2 is a block diagram of the receiving device RX.

FIG. 3 is a block diagram of the reference sampler SMe.

FIG. 4 is a block diagram of the phase adjustment circuit 11.

FIG. 5 is a block diagram of the phase interpolator 11B.

FIG. 6 is a block diagram showing the structure of the first synchronization circuit 13A.

FIG. 7 is a diagram showing the truth table of the comparison logic circuit (XOR gate).

FIG. 8 is a diagram plotting the output of the error counter on a two-dimensional plane.

FIG. 9 is a timing chart for explaining the setup time ST and hold time HD.

FIG. 10 is a block diagram of a general CDR circuit.

FIG. 11 is a timing chart for explaining the operation of the CDR circuit shown in FIG. 10.

FIG. 12 is a block diagram of the CDR circuit 17.

FIG. 13 is a timing chart for explaining the phase difference of data in the CDR circuit shown in FIG. 12.

FIG. 14 is a block diagram showing the structure of the second synchronization circuit 13B.

FIG. 15(A) is a timing chart of the serial data signal DATA-S, and FIG. 15(B) is a timing chart showing the sampling clock signal φe for reference.

FIG. 16 is a timing chart showing the serial data signal, multi-phase clock signals φ1 to φ10, and the clock signal φe.

FIG. 17 is a timing diagram of the serial data signal and the signals output from the synchronization circuits 13A and 13B.

FIG. 18 is a block diagram of another receiving device RX.

FIG. 19 is a block diagram of the phase adjustment circuit 11 shown in FIG. 18.

FIG. 20 is a block diagram showing the structure of a multi-level sampler.

FIG. 21 is a graph showing the change in input voltage (V) to the multi-level sampler over time (Time).

FIG. 22 is a block diagram showing the structure of the multi-level sampler and subsequent circuits.

FIG. 23 is a graph showing the change in input voltage (V) to the first data reception sampler SM1high and the reference sampler SMe over time (Time).

FIG. 24 is a block diagram showing the structure of the multi-level sampler and subsequent circuits.

FIG. 25 is a block diagram showing the structure of the multi-level sampler and subsequent circuits.

FIG. 26(A) and FIG. 26(B) are timing charts of exemplary serial data signals.

### DESCRIPTION OF EMBODIMENTS

Hereinafter, embodiments for implementing the present invention will be described in detail with reference to the accompanying drawings. The same reference numbers are assigned to identical elements in the drawings, and repeated descriptions are omitted. This invention is not limited to these examples, but is defined by the claims, and it is intended to include all modifications within the meaning and scope of the claims and their equivalents.

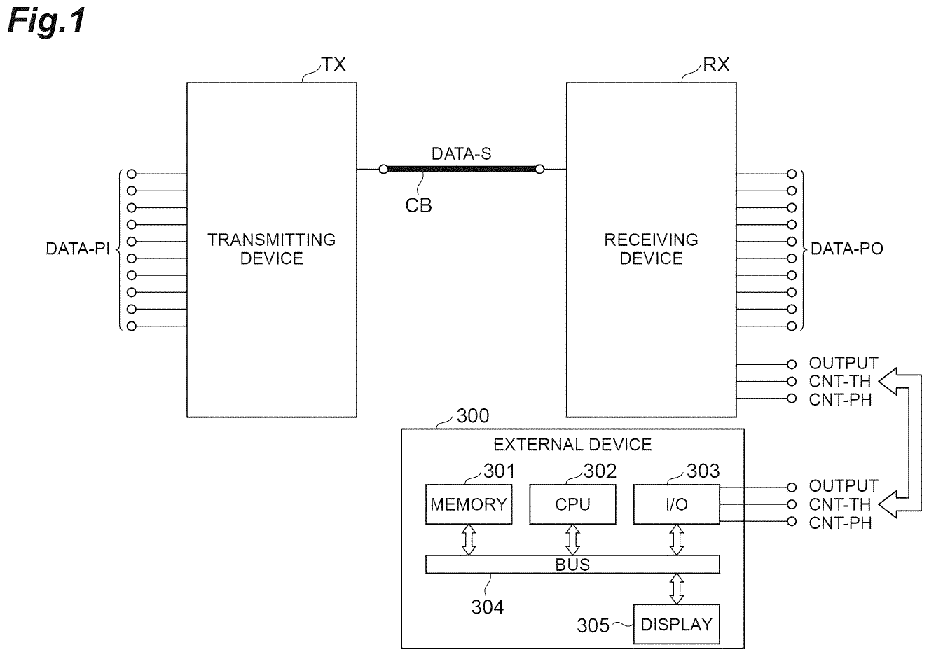

FIG. 1 is a block diagram showing a transmitting and receiving system and an external device 300.

The transmitting and receiving system includes a receiving device RX and a transmitting device TX. An external device 300 for signal quality inspection can be connected to the receiving device RX.

The transmitting device TX includes an input terminal for the input parallel data signal DATA-PI and an output terminal for the serial data signal DATA-S. The serial data signal DATA-S transmitted from the transmitting device TX is transmitted via a communication cable CB and received by the receiving device RX. For example, when transmitting 8-bit parallel data signals, the parallel data signals are serialized, and the clock is embedded in the serial data by applying 8b/10b encoding, and the 10-bit serial data signal DATA-S is transmitted.

The receiving device RX includes a deserializer that converts the received serial data signal DATA-S into parallel data signals, an output terminal for the output parallel data signal DATA-PO, and a receiving signal quality monitor (eye monitor). The receiving signal quality monitor within the receiving device RX includes an output terminal for the quality monitor signal OUTPUT, an input terminal for the external input threshold control signal CNT-TH, and an input terminal for the external input phase control signal CNT-PH. The quality monitor signal OUTPUT is a signal indicating the state of the received signal, such as an eye diagram, and includes information related to the quality of the signal.

The external device 300 is a computer and includes a memory 301, a central processing unit (CPU) 302, an interface 303, a bus 304, a display 305, an output terminal for the external input threshold control signal CNT-TH, and an output terminal for the external input phase control signal CNT-PH.

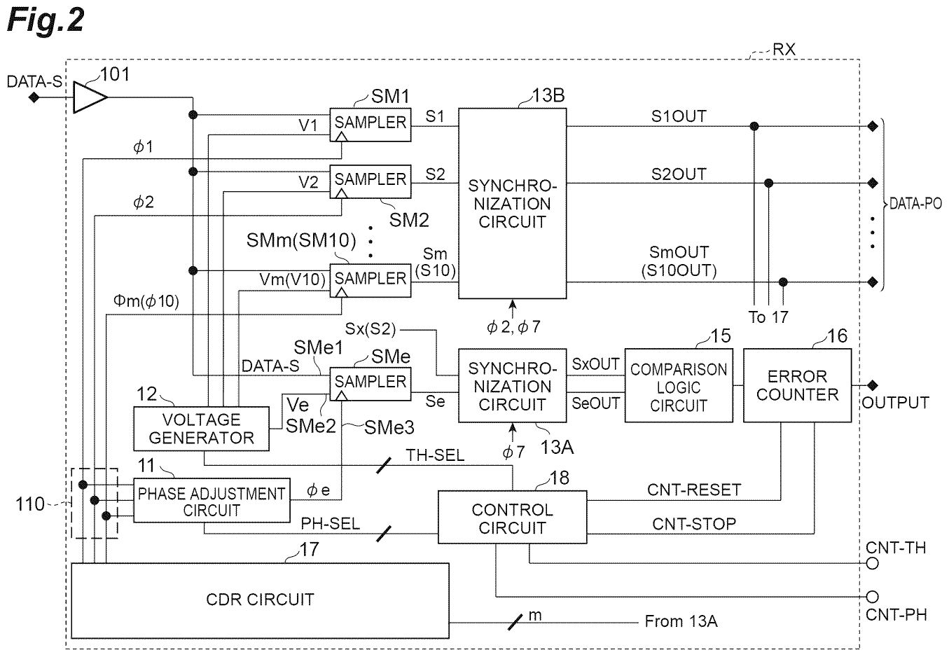

According to the control signal generation program stored in the memory 301, the central processing unit 302 performs arithmetic processing to generate the external input phase control signal CNT-PH and the external input threshold control signal CNT-TH. The external input phase control signal CNT-PH is a signal that controls the phase of the sampling clock signal pe of the phase adjustment circuit 11 (see FIG. 2) at the time (tφe) corresponding to the horizontal axis of the drawing. The external input threshold control signal CNT-TH is a signal that controls the reference threshold voltage Ve of the voltage generator 12 (see FIG. 2) at the time (tφe) corresponding to the vertical axis of the drawing. These times (tφe, tVe) are periodically reset to zero when they reach the maximum values of the horizontal and vertical axes during drawing. Also, instead of directly controlling the target parameters (phase, voltage) with these control signals, the target parameters may be controlled within the receiving device RX using these control signals as triggers.

The external device 300 receives the quality monitor signal OUTPUT output from the receiving device RX, and according to the eye diagram drawing program stored in the memory 301, the central processing unit 302 performs arithmetic processing to display the state of the received signal, such as an eye diagram, on the display 305. The eye diagram drawing program stores the quality monitor signal OUTPUT, which is output in series, in the memory 301 and then draws the eye diagram. The quality monitor signal OUTPUT includes the phase time information (tφe) of the reference sampling clock signal φe (see FIG. 2) as the information for the X-axis coordinate of the eye diagram, and the time information (tVe) of the swept reference threshold voltage Ve (see FIG. 2) as the information of the Y-axis coordinate. The error count counted by the error counter (counter) 16 (see FIG. 2) is recorded at the position defined by the two-dimensional coordinates (tφe, tVe) during drawing, and the information of the eye diagram is stored in the two-dimensional memory space. Subsequently, this program sends the obtained image information of the eye diagram to the display 305. Of course, it is also possible to store the data included in the quality monitor signal in the memory 301 of the computer and input this data into spreadsheet software to obtain the eye diagram.

The external device 300 can be realized not only by a general personal computer or a single-board computer but also by dedicated equipment or portable information terminals that perform the same signal processing as these computers.

FIG. 2 is a block diagram of the receiving device RX.

The receiving device RX includes an input terminal for the serial data signal DATA-S, and the serial data signal DATA-S is input to the amplifier 101. The amplifier 101 in this example is a simple buffer amplifier, but it may include an equalizer or a filter. The serial data signal DATA-S output from the amplifier 101 is input to the receiving signal quality monitor, and the receiving signal quality monitor outputs the quality monitor signal OUTPUT from the output terminal. The serial data signal DATA-S output from the amplifier 101 is also input to the deserializer, which includes a plurality of data reception samplers SM1 to SMm (e.g., m=10). The deserializer converts the received serial data signal DATA-S into the output parallel data signal DATA-PO and outputs it from multiple output terminals. The sampling timing of the received signal is adjusted by the CDR (Clock and Data Recovery) circuit 17, and the voltage and phase at the time of sampling are controlled by the control circuit 18. Thus, the receiving device RX includes a receiving signal quality monitor and a deserializer.

### Receiving Signal Quality Monitor

The receiving signal quality monitor utilizes the output signals of the plurality of data reception samplers SMI to SMm. The deserializer includes m samplers, and the nth sampler among them is referred to as sampler SMn. 1≤n≤m, and m and n are integers. The plurality of data reception samplers SM1 to SMm each receive the serial data signal DATA-S, are connected in parallel, and each input terminal of the sampling clock signal on receives each clock signal included in the multi-phase sampling clock signal φl to om). In the figure, as a specific example, m=10 is described, but m may be greater than or less than 10.

The receiving signal quality monitor includes the plurality of data reception samplers SMI to SMm, a reference sampler SMe that receives the serial data signal DATA-S, a phase adjustment circuit 11, a voltage generator 12, a first synchronization circuit 13A, a comparison logic circuit 15, an error counter 16, and a CDR circuit 17. The details are described below.

### Reference Sampler

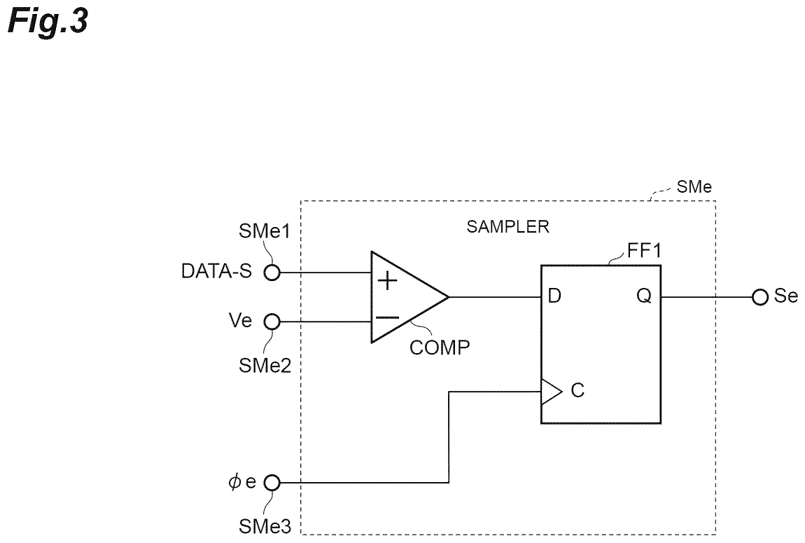

FIG. 3 is a block diagram of the reference sampler SMe.

The reference sampler SMe receives the serial data signal DATA-S. The received serial data signal DATA-S is compared with the reference threshold voltage Ve by the comparator COMP, and the comparison result is sampled at the reference sampling timing (the rise edge of the sampling clock signal φe), and the comparison result is output. As an example, a D flip-flop FF1 is used for sampling. In the D flip-flop FF1, when the rise edge of the clock signal φe is input to the C terminal while the truth value to be stored is input to the D terminal, the D flip-flop stores the truth value of the D terminal and outputs the stored truth value from the Q terminal. The output (comparison result) of the Q terminal is held until the next rise edge of the sampling clock signal φe is input.

The comparison result (second output signal (reference signal Se)) output from the reference sampler SMe indicates “1” if the serial data signal DATA-S is greater than the reference threshold voltage Ve and “0” if it is smaller. The sampling clock signal φe is output from the phase adjustment circuit 11, and the reference threshold voltage Ve is output from the voltage generator 12.

Thus, in the receiving signal quality monitor, the reference sampler SMe includes a first input terminal SMel that receives the serial data signal DATA-S, a second input terminal SMe2 that receives the reference threshold voltage Ve, and an input terminal SMe3 for the sampling clock signal φe, and samples the comparison result (reference signal Se) between the serial data signal DATA-S and the reference threshold voltage Ve in synchronization with the sampling clock signal e.

### Plurality of Data Reception Samplers

The individual structures of the plurality of data reception samplers SM1 to SMm are the same as the structure of the reference sampler SMe. The operation of each sampler SMn (n=1 to m) is described by replacing the reference threshold voltage Ve with the threshold voltage Vn (n=1 to m), the sampling clock signal pe with the sampling clock signal on (n=1 to m), and the reference signal Se with the output signal Sn (n=1 to m) in the description of FIG. 3.

### Phase Adjustment Circuit

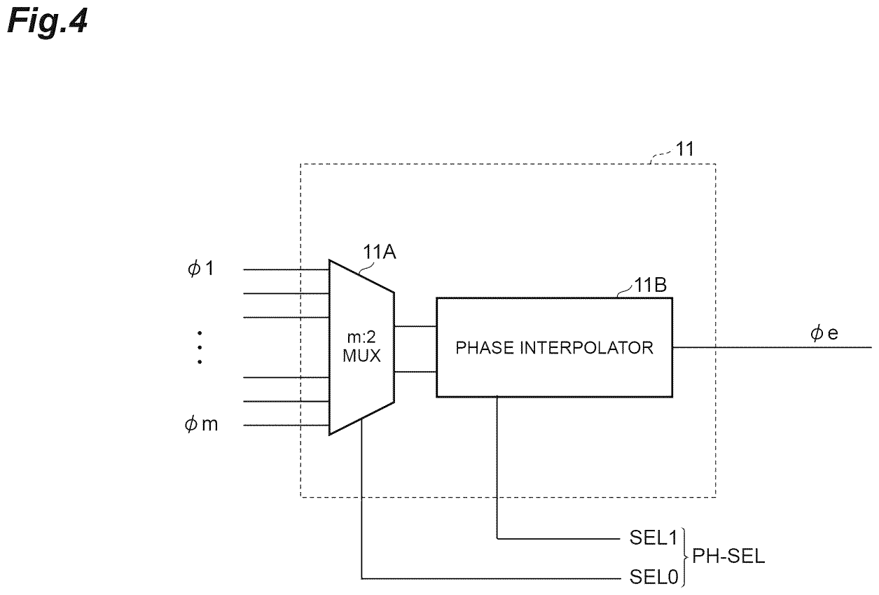

FIG. 4 is a block diagram of the phase adjustment circuit 11.

The phase adjustment circuit 11 includes one or more input terminals and an output terminal for the sampling clock signal pe. In this example, the number of input terminals of the phase adjustment circuit 11 is two or more. Two or more sampling clock signals (φ1 to φm) included in the multi-phase clock signal are input to these input terminals. The sampling clock signal φe is output from the output terminal of the phase adjustment circuit 11. The output terminal of the phase adjustment circuit 11 is connected to the input terminal for the sampling clock signal pe of the reference sampler SMe (see FIGS. 2 and 3). The phase adjustment circuit 11 can sweep the phase of the sampling clock signal φe. In this example, the phase adjustment circuit 11 receives the phase control signal PH-SEL and adjusts the phase of the sampling clock signal pe according to the received phase control signal PH-SEL. The phase control signal PH-SEL is output from the control circuit 18 (see FIG. 2). The control circuit 18 can generate the phase control signal PH-SEL based on the external input phase control signal CNT-PH. The external input phase control signal CNT-PH and the phase control signal PH-SEL may be the same signal, in which case the control circuit 18 (see FIG. 2) can be omitted.

The structure of the phase adjustment circuit 11 can take various forms, but the phase adjustment circuit shown in the figure includes a multiplexer 11A (selection circuit) and a phase interpolator 11B. The multiplexer 11A selects two clock signals φA and φB from the multi-phase clock signals φ1 to φm according to the clock selection signal SEL0 in the phase control signal PH-SEL (the values of A and B are indicated by the clock selection signal PH-SEL). The phase interpolator 11B generates and outputs a clock signal φe having a phase positioned between the two input clock signals φA and φB. The time tE of the rise edge Eve of the clock signal φe is set to a time that has elapsed by a predetermined time ΔT from the time tφof the clock signal φB is tB. The predetermined time ΔT has a value obtained by multiplying the time difference (tB−tA) by a coefficient of 1 or less, and this coefficient is given by the interpolation position selection signal SEL1 in the phase control signal PH-SEL.

As described above, the phase adjustment circuit 11 includes the multiplexer 11A, which receives the multi-phase clock signals φ1 to φm output from the CDR circuit, and the phase interpolator 11B, which receives the output signal of the multiplexer 11A. The multiplexer is a selection circuit that selects and outputs a desired signal from the input signals. The multi-phase clock signals have multiple phases, and the phase interpolator 11B can output a reference clock signal φe having a desired phase according to the phases of the two input signals and the phase control signal.

### Phase Interpolator

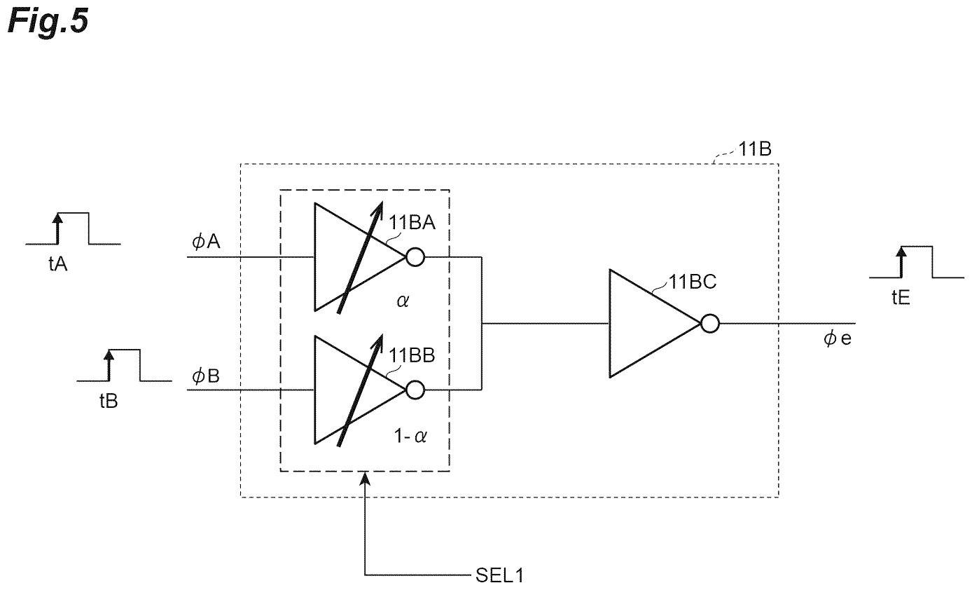

FIG. 5 is a block diagram of the phase interpolator 11B.

The phase interpolator 11B includes a first inverter 11BA to which the clock signal φA is input, a second inverter 11BB to which the clock signal φB is input, and a third inverter 11BC connected to the output terminals of these inverters. The first inverter 11BA and the second inverter 11BB each consist of multiple gated inverters connected in parallel, and the inverters have gates (transistor switches) connected in series, and the number of gates turned ON can be controlled by the interpolation position selection signal SEL1. In the first inverter 11BA, α gates are turned ON, and in the second inverter 11BB, (1-α) gates are turned ON, so the rise edge time tE of the output signal φE can be changed according to the interpolation parameter a (0<α<1).

### Voltage Generator

The voltage generator 12 shown in FIG. 2 generates multiple threshold voltages V1 to Vm (e.g., m=10) input to the plurality of data reception samplers SM1 to SMm and the reference threshold voltage Ve input to the reference sampler SMe. In this example, the voltage generator 12 receives the threshold selection signal or threshold control signal TH-SEL and changes the reference threshold voltage Ve according to the received threshold control signal TH-SEL. To obtain an eye diagram, the reference threshold voltage Ve is swept. The reference threshold voltage Ve can be swept by the voltage generator 12 itself, but in this example, the threshold control signal TH-SEL is used. The threshold control signal TH-SEL in this example is output from the control circuit 18. The control circuit 18 can generate the threshold control signal TH-SEL based on the external input threshold control signal CNT-TH. The external input threshold control signal CNT-TH and the threshold control signal TH-SEL may be the same signal, in which case the control circuit 18 can be omitted. Numerous structures are known for changing the threshold voltage according to the threshold control signal. For example, by connecting multiple resistors in parallel downstream of the node providing the threshold voltage and connecting switches in series with each resistor, the threshold voltage can be changed by controlling the ON/OFF states of these switches with the threshold control signal.

The multiple threshold voltages V1 to Vm input to the plurality of data reception samplers SM1 to SMm may be fixed values or set to the center voltage of the amplitude of the serial data signal DATA-S received by the samplers. The multiple threshold voltages V1 to Vm can also be changed as needed using feedback control or other methods. For example, by integrating the digital values of each output signal from the deserializer over a reference period, if the integrated value exceeds a first integration threshold, it is determined that the current threshold voltage is low, and the input threshold voltage to the corresponding sampler is increased, and if the integrated value falls below a second integration threshold, it is determined that the current threshold voltage is high, and a threshold control signal that decreases the input threshold voltage can be input to the voltage generator 12.

Thus, in the receiving signal quality monitor, each sampler SMn (n is any number selected from 1 to m) included in the plurality of data reception samplers SM1 to SMm includes a first input terminal that receives the serial data signal DATA-S, a second input terminal that receives the threshold voltage Vn, and an input terminal for the sampling clock signal on. The sampler samples and outputs the comparison result Sn (S1 to Sm) between the serial data signal DATA-S and the threshold voltage Vn in synchronization with the sampling clock signal on corresponding to the sampler, which is included in the multi-phase sampling clock signal.

### First Synchronization Circuit

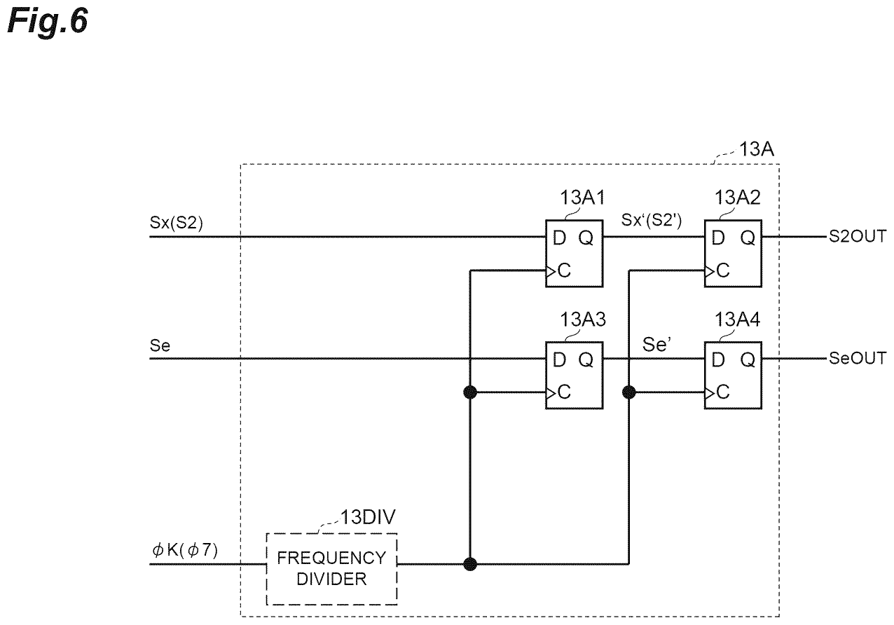

FIG. 6 is a block diagram showing the structure of the first synchronization circuit 13A.

The first synchronization circuit 13A receives the evaluation target signal Sx (first output signal (e.g., S2)) and the reference signal Se (second output signal). The evaluation target signal Sx (e.g., S2) is the output signal of one of the samplers included in the plurality of data reception samplers SM1 to SMm. The reference signal Se is the output signal of the reference sampler SMe. The first synchronization circuit 13A synchronizes the evaluation target signal Sx and the reference signal Se. The first synchronization circuit 13A outputs the synchronized evaluation target signal SxOUT and the synchronized reference signal SeOUT. The timing of the rise edges of the evaluation target signal SxOUT and the reference signal SeOUT matches.

As an example, the first synchronization circuit 13A includes a flip-flop 13A1 to which the evaluation target signal Sx is input at the D terminal, and a flip-flop 13A2 to which the output signal Sx′ of the flip-flop 13A1 is input at the D terminal. The first synchronization circuit 13A includes a flip-flop 13A3 to which the reference signal Se is input at the D terminal, and a flip-flop 13A4 to which the reference signal Se′ output from the flip-flop 13A3 is input at the D terminal. Each flip-flop is a D flip-flop, and the clock input terminal (C terminal) receives the synchronization sampling clock signal φK (e.g., φ7).

The first synchronization circuit 13A may include a frequency divider 13DIV. The frequency divider 13DIV is not essential but can reduce the frequency of the sampling clock signal. If the frequency divider 13DIV divides the sampling clock signal φK (e.g., φ7) input to the first synchronization circuit 13A by 2, the frequency of the sampling clock signal is halved, and the period is doubled.

### Comparison Logic Circuit

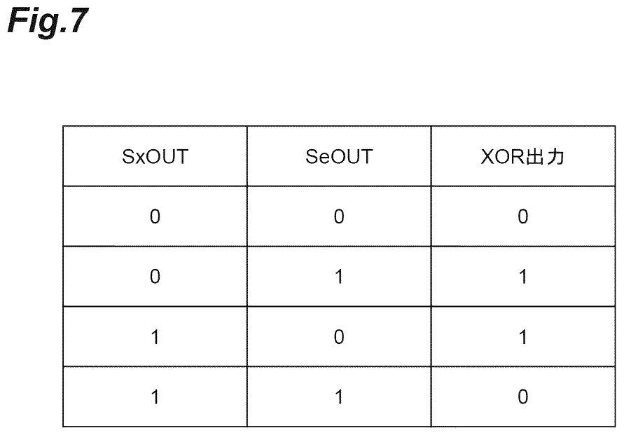

FIG. 7 is a diagram showing the truth table of the comparison logic circuit (XOR gate).

The comparison logic circuit 15 receives the evaluation target signal SxOUT and the reference signal SeOUT synchronously output from the first synchronization circuit 13A. The comparison logic circuit 15 is a circuit that compares the logic of the input digital signals, and in this example, it is an XOR gate (exclusive OR gate). The XOR gate outputs “0” if the logic of the input data matches and “1” if it differs. The XOR gate can be replaced by four NAND gates. Depending on the subsequent signal processing aspect, other logical configurations can also be adopted. For example, a circuit that inverts the output of the XOR gate with a NOT circuit can also be used. Therefore, the comparison logic circuit 15 is not limited to an XOR gate as long as it is a logic circuit that compares the logic of the input data.

### Error Counter

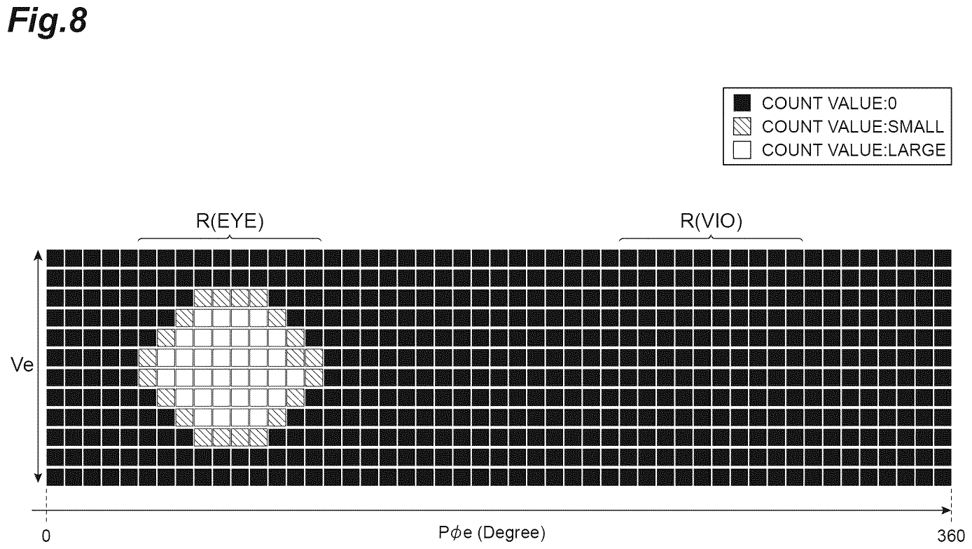

FIG. 8 is a diagram plotting the output of the error counter on a two-dimensional plane.

The error counter 16 (see FIG. 2) is a counter that counts the output result (digital data) of the comparison logic circuit 15. The error counter 16 increments the count when the input data to the comparison logic circuit 15 (evaluation target signal Sx, reference signal Se) do not match. The comparison results are counted and accumulated over a certain period (referred to as E-COUNT), and the count value is output. The phase of the reference rise edge (e.g., Eφ8) is set to 0°. The reference signal Se is a signal sampled at the rise edge Eve of the sampling clock signal φe, which is a phase Poe (degrees) away from the reference rise edge. The count value indicates the degree of mismatch between the evaluation target signal Sx and the reference signal Se at the coordinates (Pφe, Ve) (pixel). When drawing a two-dimensional graph with the phase Pφe as the horizontal axis and the reference threshold voltage Ve as the vertical axis, the count value of the error counter 16 at the position of the coordinates (Pφe, Ve) draws the eye diagram. Pixels with low count values indicate regions within the eye opening of the eye diagram, and within the eye opening of the eye diagram, the count value is essentially zero.

The phase range of the eye diagram formation region R (EYE) drawn on the two-dimensional plane is at most ½ of the maximum value of the phase Poe (N×UI, 360°) in this example, preferably ⅓ or less, and more preferably ¼ or less. N is a natural number, and UI indicates the unit interval of the serial data signal DATA-S. In other words, the maximum value of the phase Poe is greater than the phase range of the eye diagram formation region R (EYE) necessary for data acquisition. The center of the error tolerance region R (VIO) is set at a position approximately (N×UI×½, 180°) away from the center of the eye diagram formation region R (EYE). The phase range of the error tolerance region R (VIO) is at most ½ of the maximum value of the phase Poe, preferably ⅓ or less, and more preferably ¼ or less. In the error tolerance region R (VIO), setup time violations and/or hold time violations may occur between the reference signal Se and the sampling clock signal φ7 in the first synchronization circuit 13A. In short, errors occur in the error tolerance region R (VIO). In this example, the error tolerance region R (VIO) is separated from the eye diagram formation region R (EYE), and the eye diagram formation region R (EYE) is not affected by errors.

The positions on the horizontal axis of the eye diagram formation region R (EYE) and the error tolerance region R (VIO) shift along the horizontal axis from the reference position according to the inherent delay amount caused by changes in the operating temperature or manufacturing variations of the phase adjustment circuit. Also, the positions of phase Pφe=360° and phase Pφe-0° are the same, and the left and right ends of the graph may be continuously connected. If the inherent delay amount increases, part of the eye diagram may appear near the left end of the graph, and the remaining part may appear near the right end of the graph. In this device, even if the inherent delay amount of the phase adjustment circuit changes, the eye diagram formation region R (EYE) is separated from the error tolerance region R (VIO) and is not affected by errors.

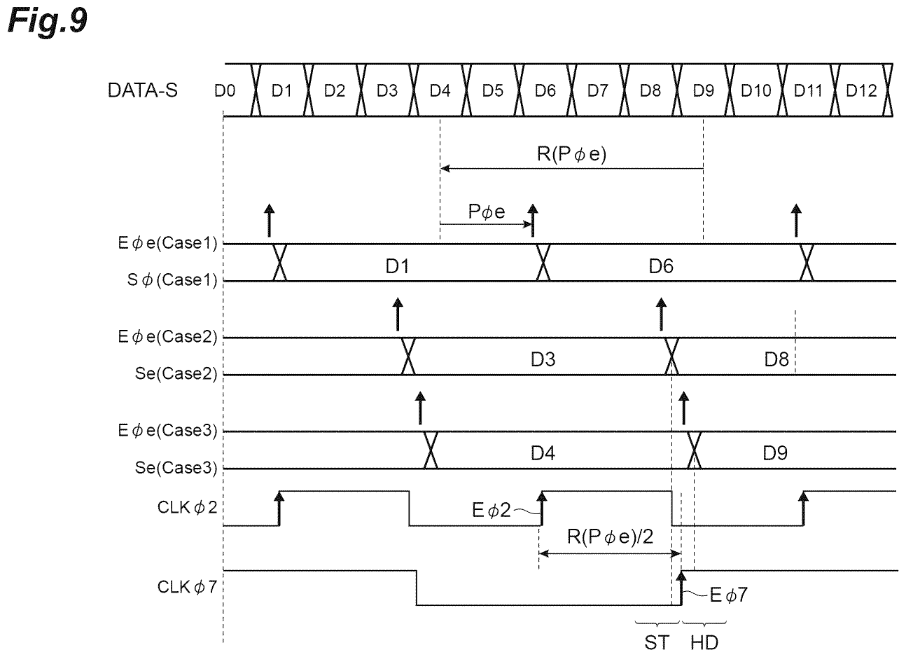

FIG. 9 is a timing chart for explaining the setup time ST and hold time HD.

Referring to FIG. 2, the first synchronization circuit 13A receives the sampling clock signal φ7 as the synchronization signal, and the evaluation target signal Sx and the reference signal Se are set as the input signals to be synchronized. In this example, it is assumed that the evaluation target signal Sx (e.g., S2) is sampled by the sampling clock signal φ2 in the sampler SM2.

The phase Poe varies within the range R (Pφe) of 5 UIs of the serial data signal DATA-S.

In the first case (Case 1), the rise edge Eve of the sampling clock signal pe coincides with the positions of data D1 and data D6, and in the reference signal Se, the truth value of data D1 is followed by the truth value of data D6. In this case, since there is no data boundary position of the reference signal Se within the vicinity range (setup time ST, hold time HD) of the rise edge Eφ7 of the sampling clock signal φ7, no setup time violation or hold time violation occurs.

In the second case (Case 2), the rise edge Eφe of the sampling clock signal φe coincides with the positions of data D3 and data D8, and in the reference signal Se, the truth value of data D3 is followed by the truth value of data D8. In this case, since there is a data boundary position of the reference signal Se within the vicinity range (setup time ST) of the rise edge Eφ7 of the sampling clock signal φ7, a setup time violation occurs.

In the third case (Case 3), the rise edge Eve of the sampling clock signal e coincides with the positions of data D4 and data D9, and in the reference signal Se, the truth value of data D4 is followed by the truth value of data D9. In this case, since there is a data boundary position of the reference signal Se within the vicinity range (hold time HD) of the rise edge Eφ7 of the sampling clock signal φ7, a hold time violation occurs.

In this example, to sufficiently separate the region where these errors occur from the eye diagram formation region, the time from the rise edge Eφ2 of the sampling clock signal φ2 of the evaluation target signal Sx (e.g., S2) to the rise edge Eφ7 of the sampling clock signal φ7 is set to R (Pφe)/2 (2.5 UI). For this purpose, for example, it can be set to 2≤(R (Pφe)/2)≤8.

### CDR Circuit

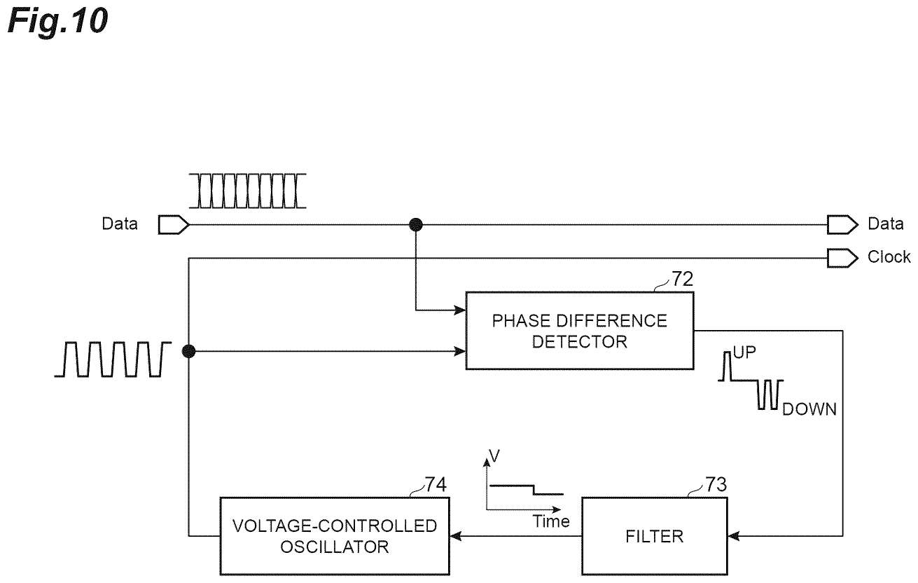

FIG. 10 is a block diagram of a general CDR circuit.

This CDR circuit includes a phase difference detector 72, a filter 73, and a voltage-controlled oscillator 74. The phase difference detector 72 receives the serial data signal Data and the clock signal Clock. The CDR circuit generates the clock signal based on the edge information of the input data.

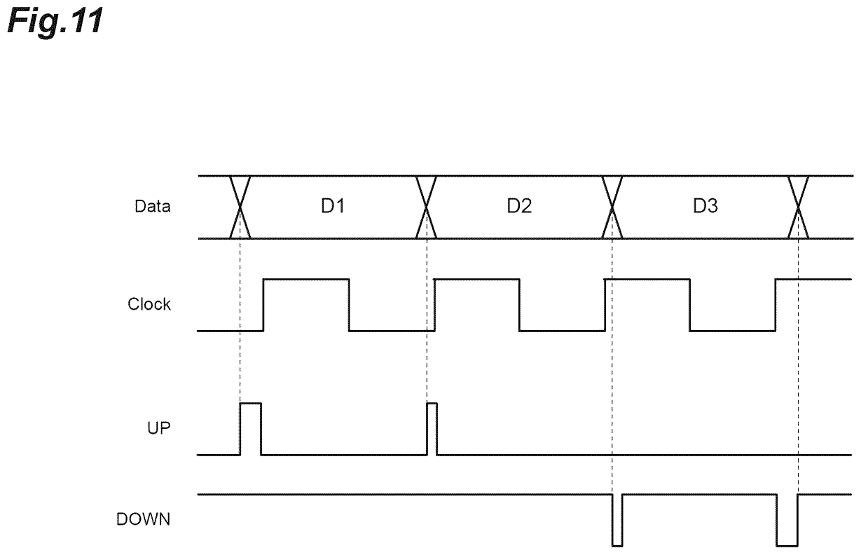

FIG. 11 is a timing chart for explaining the operation of the CDR circuit shown in FIG. 10.

The phase difference detector 72 detects the phase difference between the edge position of the serial data signal Data and the rise edge position of the clock signal Clock, and outputs a positive pulse signal UP with a width corresponding to the phase difference if the position of the serial data signal Data is ahead, and a negative pulse signal DOWN with a width corresponding to the phase difference if it is behind. The (low-pass) filter 73 integrates and smooths the positive pulse signal UP and the negative pulse signal DOWN and outputs a voltage corresponding to the phase difference. The voltage-controlled oscillator 74 decreases the repetition frequency of the clock signal Clock if the phase is ahead of the reference (the integrated value of the width of the positive pulse signal is large, and the input voltage is positive), and increases the repetition frequency of the clock signal Clock if the phase is behind the reference (the integrated value of the width of the negative pulse signal is large, and the input voltage is negative).

Note that the CDR circuit 17 shown in FIG. 2 is placed downstream of the second synchronization circuit 13B, so parallel data signals are input, and it differs from the CDR circuit with the structure shown in FIG. 10. When applying the CDR circuit with the structure shown in FIG. 10 to the receiving device shown in FIG. 2, for example, the serial data signal DATA-S and the individual sampling clock signals on (φ1 to φm) can be input to the CDR circuit, and the sampling clock signals on (φ1 to φm) can be generated based on these input signals.

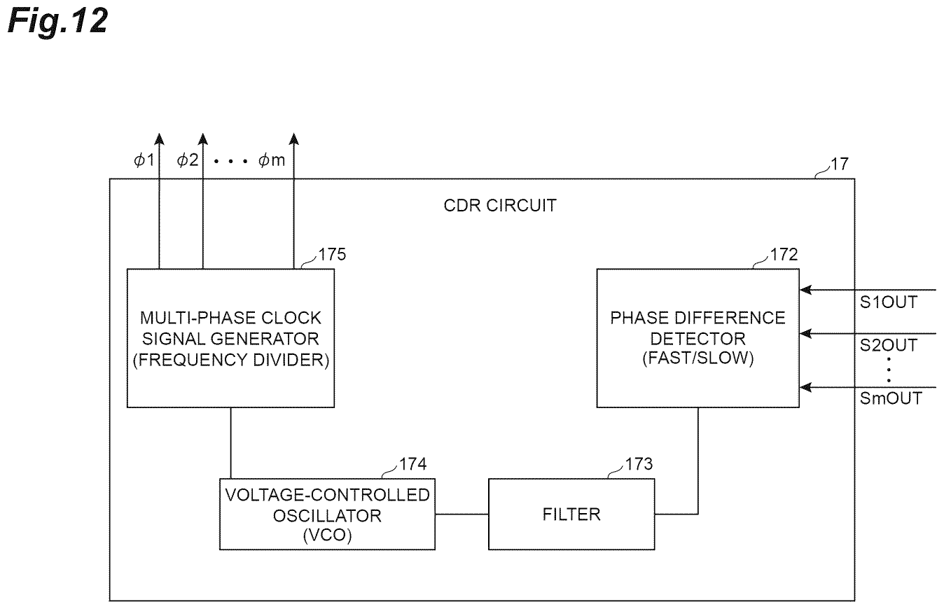

FIG. 12 is a block diagram of the CDR circuit 17.

The CDR circuit 17 is placed downstream of the second synchronization circuit 13B and includes a phase difference detector 172, a filter 173, a voltage-controlled oscillator 174, and a multi-phase clock signal generator 175. The CDR circuit 17 receives the parallel data signals (digital signals SIOUT to SmOUT) output from the second synchronization circuit 13B.

Each digital signal SIOUT to SmOUT has information of “1” or “0”. The sequences of these “1” and “0” as a whole have phase difference information. In other words, this phase difference information is the phase difference information between the phase of the serial data signal DATA-S and the phase of the sampling clock signal in the data reception samplers SM1 to SMm. This phase difference information indicates whether the phases of the sampling clock signals φ1 to φm are ahead (FAST) or behind (SLOW) the phase of the serial data signal DATA-S.

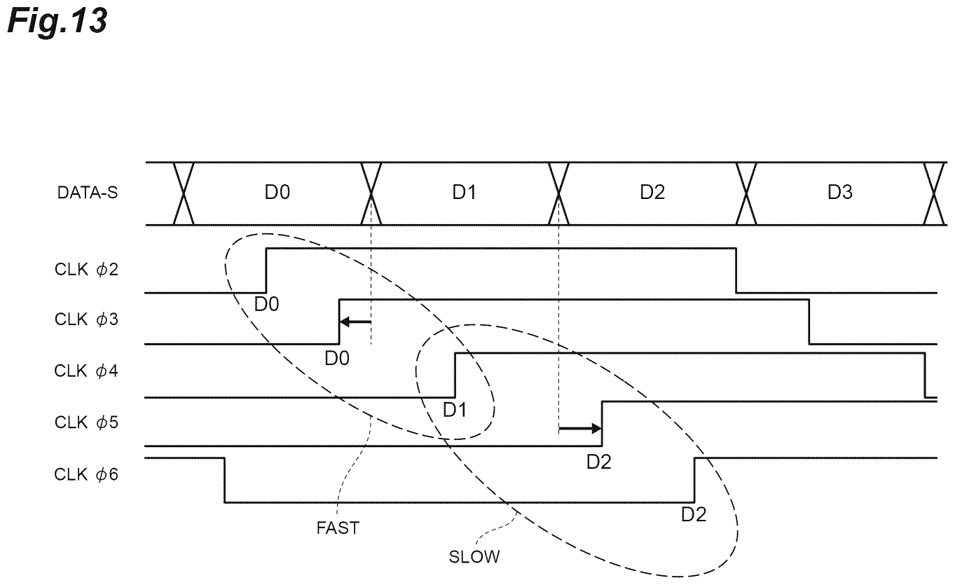

FIG. 13 is a timing chart for explaining the phase difference of data in the CDR circuit shown in FIG. 12.

Among the digital signals S1OUT to SmOUT shown in FIG. 12, the odd-numbered signals (S1OUT, S3OUT, S5OUT, S7OUT, S9OUT) have data sampled at the edge positions of the serial data signal DATA-S in the odd-numbered samplers (SM1, SM3, SM5, SM7, SM9) shown in FIG. 2. The even-numbered signals (S2OUT, S4OUT, S6OUT, S8OUT, S10OUT) are sampled at the central positions of the pulse widths of the serial data signal DATA-S.

In this case, if the data sequences of the digital signals S2OUT, S3OUT, and S4OUT sampled by the sampling clock signals φ2, φ3, and φ4 are, for example, “0, 0, 1” or “1, 1, 0”, the rise edge of the sampling clock signal φ3 is ahead of the edge of the serial data signal DATA-S (FAST).

Conversely, if the data sequences of the digital signals S4OUT, S5OUT, and S6OUT sampled by the sampling clock signals φ4, φ5, and φ6 are “0, 1, 1” or “1, 0, 0”, the rise edge of the sampling clock signal φ5 is behind the edge of the serial data signal DATA-S (SLOW).

In cases other than these data sequences, such as “1, 0, 1” or “1, 1, 1”, they are ignored as exceptions.

Referring again to FIG. 12, the phase difference detector 172 detects whether the rise edge positions of the odd-numbered sampling clock signals (φ1, φ3, φ5, φ7, φ9) are ahead of or behind the data boundary positions of the serial data signal based on the data sequences of the input digital signals S1OUT to SmOUT, for example, 10-digit digital data. The phase difference detector 172 stores a judgment table for the data sequences in the FAST and SLOW cases and outputs “1” if it matches the former and “0” if it matches the latter. This allows the phase difference detector 172 to determine the FAST/SLOW state based on the input data. The logic circuit that determines the match of three data can be configured, for example, by placing three AND gates in parallel and inputting the outputs of these three AND gates into a three-input AND gate.

When the phase difference information signal (e.g., four FASTs and one SLOW, sequence “1, 1, 1, 1, 0”) is output from the phase difference detector 172, the (low-pass) filter 173 integrates and smooths these pulse signals and outputs a DC voltage. In this case, since the phase of the sampling clock signal is determined to be ahead as a whole, the voltage-controlled oscillator 174 decreases the repetition frequency of the clock signal. This operation is the same as the general CDR circuit operation shown in FIG. 10, and if it is determined to be behind as a whole, the opposite operation is performed. Other methods for controlling the repetition frequency of the clock signal in the CDR circuit are also known and can be used.

As described above, in the CDR circuit 17, if the number of FASTs is large, the clock frequency of the voltage-controlled oscillator is decreased, and if the number of SLOWs is large, the clock frequency of the voltage-controlled oscillator is increased. By repeating this process, the rise edges of the odd-numbered sampling clock signals among φ1 to φm will align with the edges of the serial data signal DATA-S, resulting in sampling clock signals that are aligned with the serial data signal.

The clock signal output from the voltage-controlled oscillator 174 is input to the multi-phase clock signal generator 175. The multi-phase clock signal generator 175 generates multiple sampling clock signals φ1 to φm with different phases from the input clock signal. The multi-phase clock signal generator 175 can be configured, for example, using one or more frequency dividers. It is also possible to connect multiple delay circuits in series downstream of one frequency divider and output each sampling clock signal from the output terminals of the delay circuits. Another configuration is to connect multiple frequency dividers in parallel and vary the reset timing of each frequency divider. Since many types of multi-phase clock signal generators have been known, known circuits can be adopted.

As described above, the receiving signal quality monitor includes a second synchronization circuit 13B to which multiple output signals S1 to Sm output from the plurality of data reception samplers SMI to SMm are input, and a CDR circuit 17 that receives the multiple output signals SIOUT to SmOUT output from the second synchronization circuit 13B and generates the multi-phase clock signals φl to φm. Note that the CDR circuit 17 may input only a part of the output signals selected from SIOUT to SmOUT instead of all the output signals.

### Control Circuit

The control circuit 18 generates and outputs the phase control signal PH-SEL input to the phase adjustment circuit 11 and the threshold control signal TH-SEL input to the voltage generator 12. The control circuit 18 outputs the reset control signal CNT-RESET and the stop control signal CNT-STOP input to the error counter 16. As described above, in the error counter 16, when drawing a two-dimensional eye diagram, the number of errors corresponding to each pixel of the eye diagram is counted over a certain period (E-COUNT). This specific period (E-COUNT) is definedd from the input timing of the reset control signal CNT-RESET to the input timing of the stop control signal CNT-STOP, the former input resets the error counter 16, and the latter input ends the count and outputs the count value.

### Deserializer

The deserializer includes the plurality of data reception samplers SMI to SMm and the second synchronization circuit 13B.

The structure of each sampler SMn (SMI to SMm) is the same as the structure of the reference sampler SMe shown in FIG. 3. Note that the plurality of data reception samplers SM1 to SMm are also part of the receiving signal quality monitor. The serial data signal DATA-S received by the plurality of data reception samplers SMI to SMm is sampled in synchronization with the multi-phase sampling clock signals φ1 to φm. The plurality of data reception samplers each receive the serial data signal, are connected in parallel, and each receives the multi-phase sampling clock signal φ1 to φm.

### Second Synchronization Circuit

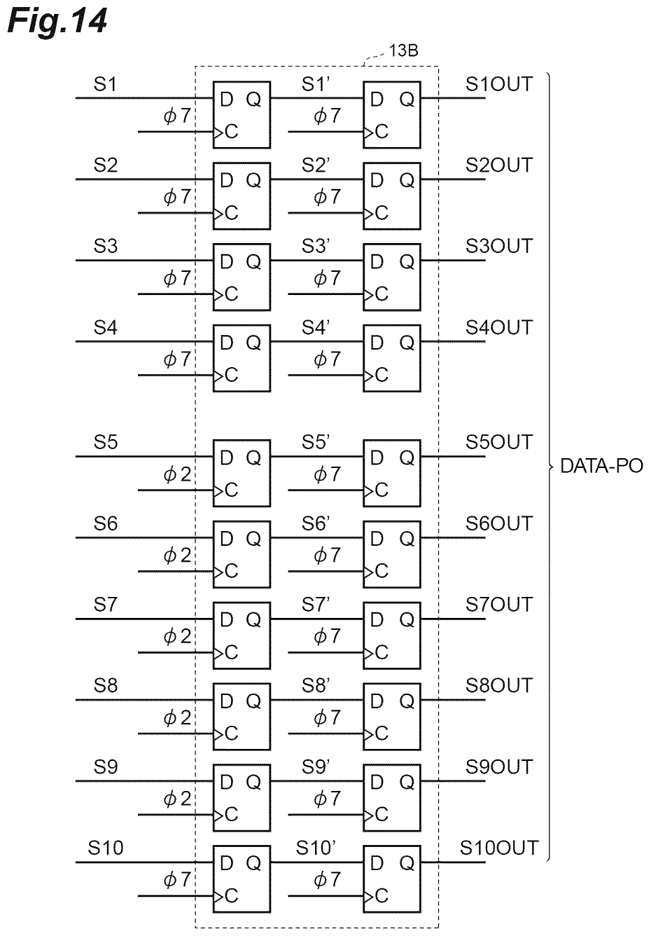

FIG. 14 is a block diagram showing the structure of the second synchronization circuit 13B.

The second synchronization circuit 13B receives the output signals S1 to Sm (e.g., m=10) output from the plurality of data reception samplers SMI to SMm. The second synchronization circuit 13B synchronizes the timing of the received output signals S1 to Sm and outputs them as parallel data output signals DATA-PO (SIOUT to SmOUT). Each output signal Sn (S1 to Sm) is input to a flip-flop group consisting of two flip-flops connected in series. Each flip-flop is a D flip-flop.

The first output signal Sn (1≤n≤m) is input to the D terminal of the front flip-flop of the nth flip-flop group. The clock input terminal (C terminal) of the front flip-flop of the flip-flop groups for n=1, 2, 3, 4, and 10 receives the synchronization sampling clock signal φK (e.g., φ7). The clock input terminal (C terminal) of the front flip-flop of the flip-flop groups for n=5, 6, 7, 8, and 9 receives the synchronization sampling clock signal φL (e.g., φ2).

The D terminal of the rear flip-flop of the nth flip-flop group receives the first output signal Sn′ (1≤n≤m) sampled by the front flip-flop. The clock input terminal (C terminal) of the rear flip-flop of the nth flip-flop group receives the synchronization sampling clock signal φK (e.g., φ7).

In other words, the second synchronization circuit 13B performs the final synchronization using the sampling clock signal φK (e.g., φ7). The data for even-numbered n (2, 4, 6, 8, 10) are sampled at the midpoint of the pulse width of the serial data signal DATA-S. The output data can be arranged in the order of n=10, 2, 4, 6, 9.

Next, the data sampling will be supplemented.

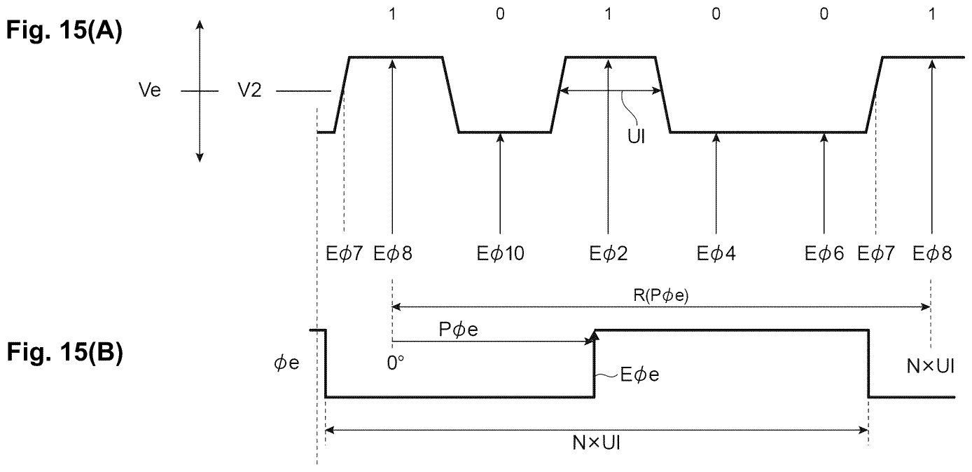

FIG. 15(A) is a timing chart of the serial data signal DATA-S, and FIG. 15(B) is a timing chart showing the sampling clock signal φe for reference.

The reference sampler SMe receives the serial data signal DATA-S and the sweepable reference threshold voltage Ve. The serial data signal DATA-S is, for example, “1, 0, 1, 0, 0, 1”. The position of the rise edge Epe of the sampling clock signal pe can be moved and swept in the time axis direction by the phase adjustment circuit 11 (see FIG. 2). The figure also shows the threshold voltage V2 for the sampler SMn (e.g., SM2) used in the deserializer and the rise edge Eφn (e.g., Eφ2) of its sampling clock signal on (e.g., φ2). The sampler SM2 samples the serial data signal at the rise edge Eφ2 and outputs “1”. The width of one data of the serial data signal DATA-S is UI (unit interval).

For example, the reference position (0°) of the sweepable rise edge Eφe is set to the position of the initial eighth rise edge Eφ8. The phase Pφe of the rise edge Eφe can be swept to the position of the next eighth rise edge Eφ8, and in terms of UI, the phase Pφe can vary from 0 to N×UI (e.g., N=5), and the phase variation range R (Poe) is N×UI. In terms of phase angle, the phase Poe can vary from 0° to 360° (0°≤Pφe≤360°), and the phase variation range R (Pφe) is 360°. The period Tφe of the sampling clock signal pe can be set to Tφe=N×UI, but since the position of the rise edge Epe is needed, it may have a different period. Also, for the same reason, the duty cycle of the sampling clock signal φe does not necessarily have to be 50%.

Regarding the period (Tφe=N×UI) of the sampling clock signal φe, to reduce the sampling frequency, it is preferable that 2≤N. Also, as described above, to suppress the effects of setup time violations and hold time violations on the eye diagram, it is preferable that 3≤N, and more preferably 4≤N. Also, if the duty cycle of the sampling clock signal is 50% and N is an odd number, the phase of the rise edge increases by a factor of 2 due to signal inversion, so it is preferable to set the parallel data signal to X=2×N bits (e.g., 10 bits). Therefore, N=5, 7 is preferable, but similar effects can be expected with N=2, 3, 4, 6.

Note that if the clock frequency f of the sampling clock signal φe (or the sampling clock signals φ1 to φ10) is given by the reciprocal of the time T of one data unit (f=1/T), it is called full-rate transmission. If the clock frequency f is ¼T, it is called quarter-rate transmission. If the clock frequency f is 1/(NT), it can be called (1/N) rate transmission. For example, in the above, 1/N rate transmission (e.g., N=5) is performed using m-phase clocks (m=10) (m and N are integers, 2≤m, 2≤N, N≤m). Note that the number of clock signal lines required for clock signal transmission is determined by the number of required clock signal phases, but in many cases, it is N or 2×N.

As described above, the reference threshold voltage Ve is varied and swept by the voltage generator 12. Thus, the receiving signal quality monitor includes a voltage generator 12 that generates the variable reference threshold voltage Ve, the variable reference threshold voltage Ve provides the vertical axis coordinates when drawing the eye diagram. By varying the reference threshold voltage Ve, the coordinates (Poφe, Ve) when drawing the two-dimensional eye diagram can be varied along the vertical axis. By varying the value of the phase Pφe by the phase adjustment circuit 11, the coordinates (Pφe, Ve) when drawing the two-dimensional eye diagram can be varied along the horizontal axis.

Also, the threshold voltage Vn (e.g., V2) of any sampler can be varied by the voltage generator 12. Thus, the receiving signal quality monitor includes a voltage generator 12 that generates the variable threshold voltage Vn (V1 to Vm). The threshold voltages Vn (V1 to Vm) input to the plurality of data reception samplers can be feedback controlled to be the center of the amplitude of the serial data signal input to each sampler SMn (SM1 to SMm). For example, if the serial data signal DATA-S is an 8b/10b encoded signal, the number of “1”s and “0”s output from each sampler is counted over a predetermined period, and if the number of “1”s is greater than the number of “0”s, it is determined that the threshold voltage Vn is lower than the center voltage of the amplitude of the serial data signal DATA-S, and the reference threshold voltage Ve is increased. If the number of “1”s is lower, the reference threshold voltage Ve is decreased.

The threshold voltages Vn input to the plurality of data reception samplers are preferably set so that the input signal levels can be clearly distinguished. For example, if the level of data “1” is 1V and the level of “0” is −1V, the threshold voltage is set to 0V. Also, for example, if the level of data “1” is 2V and the level of “0” is 0V, the threshold voltage is set to 1V.

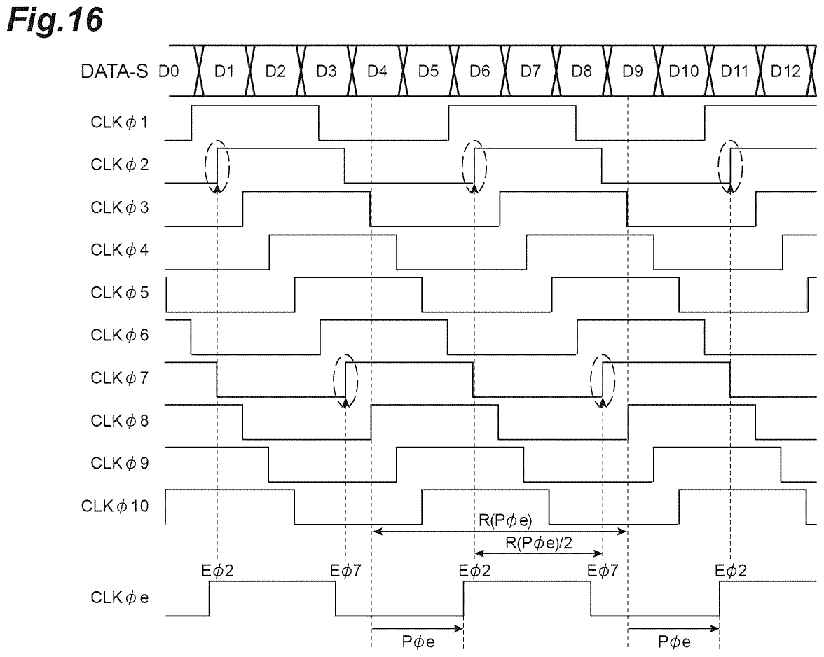

FIG. 16 is a timing chart showing the serial data signal, multi-phase clock signals φ1 to φ10, and the clock signal e.

The first synchronization circuit 13A (see FIG. 2) receives two signals. One signal is the signal obtained by sampling the serial data signal DATA-S at the rising edge Eqφ2 of the sampling clock signal φ2. The other signal is the signal obtained by sampling the serial data signal DATA-S at the rising edge Eve of the sampling clock signal φe. The second synchronization circuit 13B (see FIG. 2) receives the signals sampled by the sampling clock signals on (e.g., φ1 to φ10). These synchronization circuits output the sampled data at the timing of the synchronization sampling clock signal φ7.

The phase Pφe of the rise edge Eve shifts within the phase variation range R (Pφe). If one of the signals input to the first synchronization circuit 13A is obtained by sampling at the rise edge Eon (e.g., Ev2), it is preferable to set the phase interval from Eφ2 to Eφ7 to R (Pφe)/2 (=2.5 UI). In other words, if the parallel data signal converted from the serial data signal is X bits, the phase interval (time) from the first rise edge Eon to the second rise edge Eφ(n+X/2) is set to (X/4)×UI. As described above, the phase variation range R (Poφe) is preferably set to 5×UI (=(X/2 )×UI).

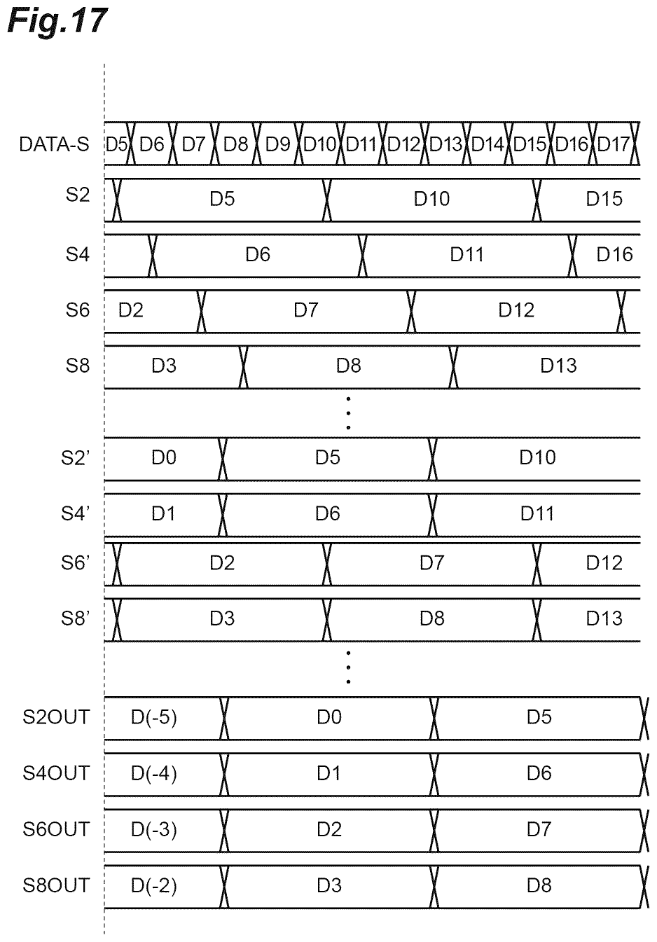

FIG. 17 is a timing diagram of the serial data signal and the signals output from the synchronization circuits 13A and 13B.

The data of the digital signals S2, S4, S6, and S8 sampled by the even-numbered samplers SMn (where n is even) are converted into the data of the digital signals S2′, S4′, S6′, and S8′ by the front flip-flops of the 2nd synchronization circuit 13B (see FIG. 14). Subsequently, they are converted into the data of the digital signals S2OUT, S4OUT, S6OUT, and S8OUT by the rear flip-flops, and are output from the 2nd synchronization circuit 13B with the phase of the data edges aligned.

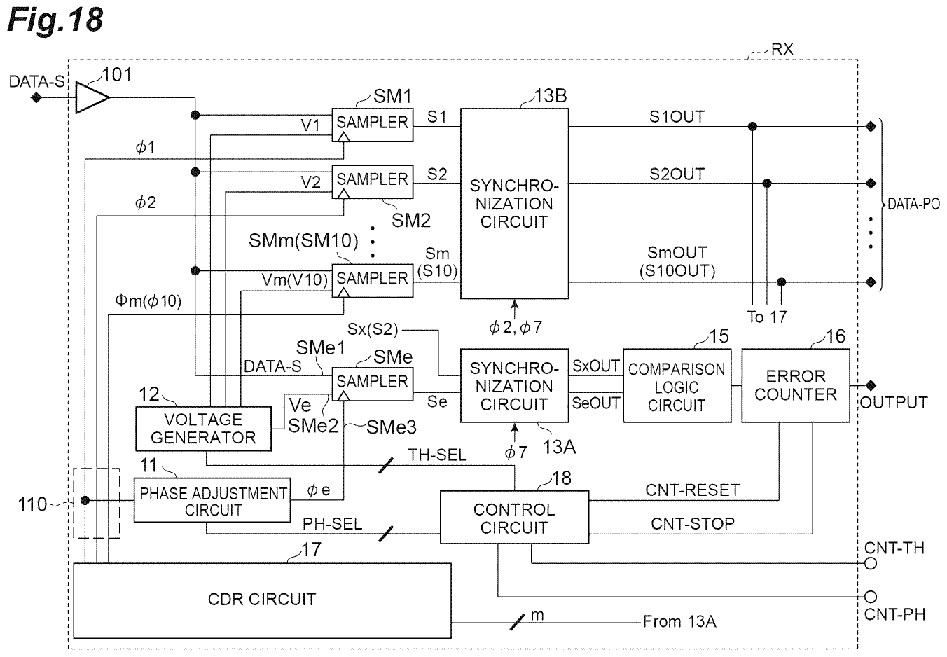

FIG. 18 is a block diagram of another receiving device RX.

The receiving device RX shown in FIG. 18 differs from the receiving device RX shown in FIG. 2 only in the structure of the phase adjustment circuit 11 and the input section 110, and the other structures are the same. The input section 110 in this example has a connection structure that inputs only one sampling clock signal φ1 to the phase adjustment circuit 11. The sampling clock signal input to the phase adjustment circuit 11 may be a sampling clock signal other than φ1.

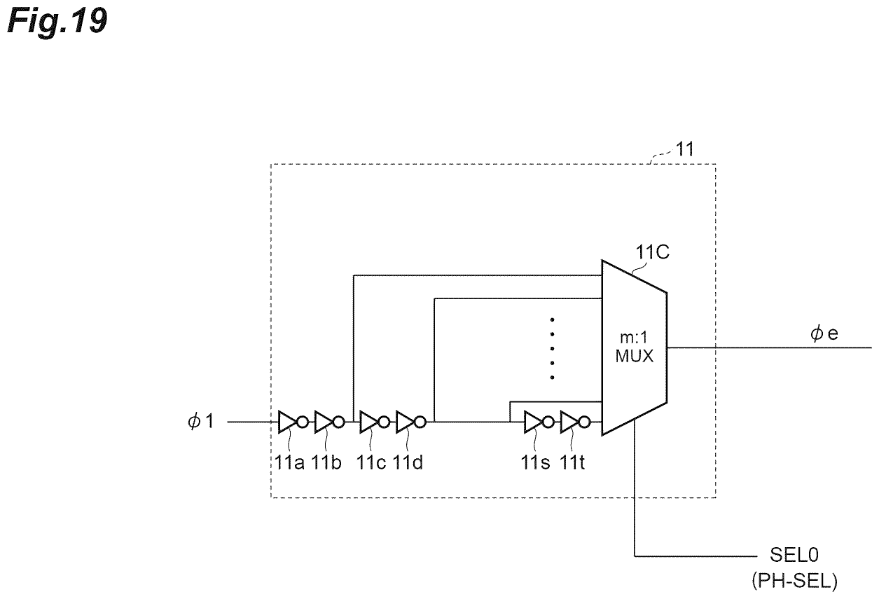

FIG. 19 is a block diagram of the phase adjustment circuit 11 shown in FIG. 18.

The phase adjustment circuit 11 receives a single sampling clock signal φ1. Multiple inverter circuits (NOT gates 11a, 11b, 11c, 11d . . . 11s, 11t) are connected in series, and the output terminals of every two inverter circuits are input to the multiplexer 11C (selection circuit). A pair of inverter circuits form a delay circuit, and the input sampling clock signal φ1 is delayed and output. The multiplexer 11C receives multiple sampling clock signals with different rise edge times. The phase control signal PH-SEL (phase or clock selection signal SEL0) selects one sampling clock signal from the m sampling clock signals input to the multiplexer 11C and outputs the sampling clock signal φe with a specific phase. By switching the signal selected by the phase control signal PH-SEL (phase or clock selection signal SEL0), the phase of the sampling clock signal pe can be adjusted and swept.

The transmission method of the serial data signal described above is, for example, an NRZ (Non-Return-to-Zero) signal, and the serial data signal has two voltage levels. Therefore, each sampler receives one threshold voltage and can determine the two levels. PAM4 (Pulse Amplitude Modulation 4) is a signal transmission method that uses four voltage levels. When using a PAMk (3≤k) signal transmission method with three or more voltage levels, a multi-level sampler that can distinguish these levels is used. In the above, the plurality of data reception samplers SM1 to SMm are shown, but since they have the same structure, the structure of one data reception sampler SM1 will be described as a representative of these samplers, modified to a multi-level sampler.

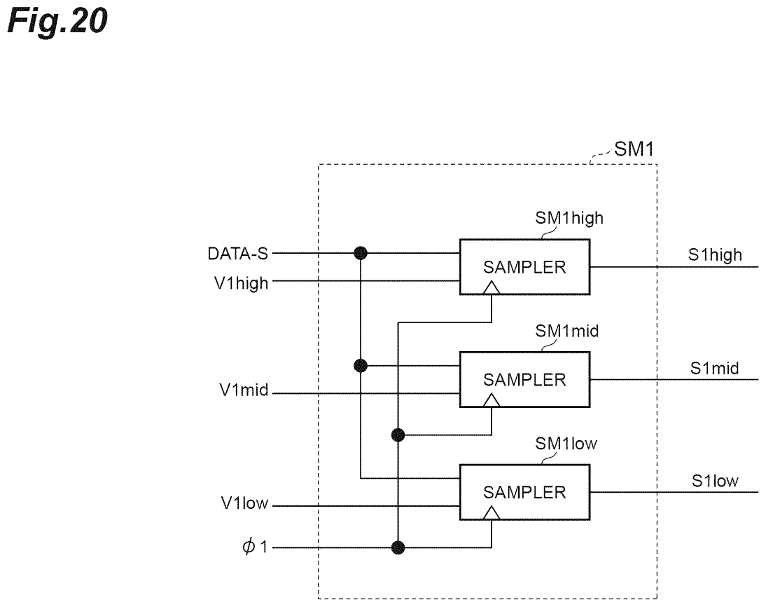

FIG. 20 is a block diagram showing the structure of a multi-level sampler.

When receiving a serial data signal (PAM4) with four voltage levels, three threshold voltages are required to distinguish these levels, resulting in an eye diagram with three eye openings. In general, when receiving a serial data signal with k levels, k−1threshold voltages are required to distinguish these levels, resulting in an eye diagram with k−1 eye openings. The figure shows the case of receiving a PAM4 serial data signal, and the data reception sampler SM1 includes a first data reception sampler SM1high, a second data reception sampler SM1mid, and a third data reception sampler SM1low, each having the same structure as shown in FIG. 3. Each sampler receives a high-level threshold voltage V1high (first threshold voltage), a mid-level threshold voltage V1mid (second threshold voltage), and a low-level threshold voltage V1low (third threshold voltage). Each sampler receives the first sampling clock signal φ1 and outputs the first output signal S1high, the second output signal S1mid, and the third output signal S11ow.

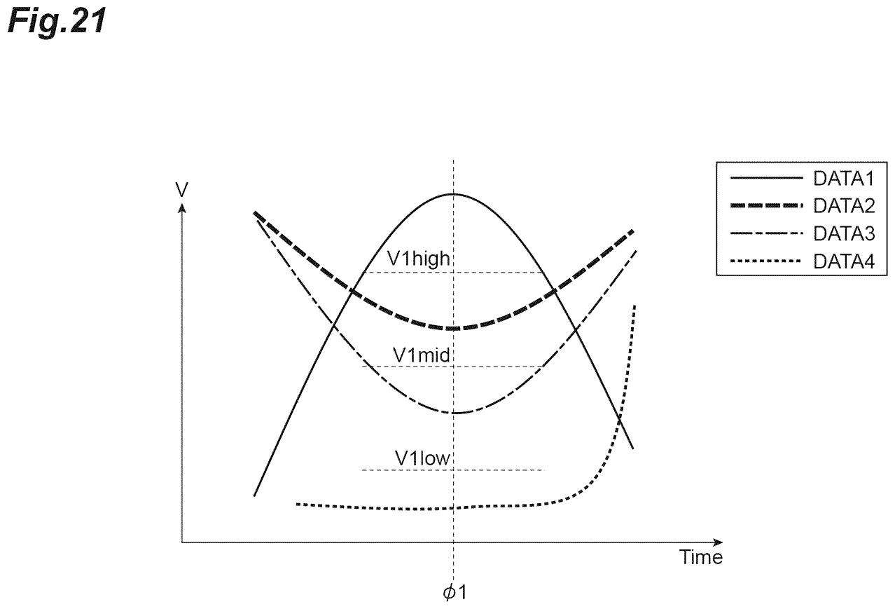

FIG. 21 is a graph showing the change in input voltage (V) to the multi-level sampler over time (Time).

When the data included in the serial data signal is the first data DATA1, and this is input to the first data reception sampler SM1high, the second data reception sampler SM1mid, and the third data reception sampler SM1low, the input voltage at the sampling timing of the sampling clock signal φ1 is higher than all the threshold voltages, so the outputs of the first, second, and third samplers (S1high, S1mid, S1low) are (1, 1, 1). Using a data conversion table, (1, 1, 1) can be converted to “11”.

Similarly, when the data included in the serial data signal is the second data DATA2, and this is input to the first data reception sampler SM1high, the second data reception sampler SM1mid, and the third data reception sampler SM1low, the outputs of the first, second, and third samplers (S1high, S1mid, S1low) at the sampling timing of the sampling clock signal φ1 are (0, 1, 1). Using a data conversion table, (0, 1, 1) can be converted to “10”.

Similarly, when the data included in the serial data signal is the third data DATA3, and this is input to the first data reception sampler SM1high, the second data reception sampler SM1mid, and the third data reception sampler SM1low, the outputs of the first, second, and third samplers (S1high, S1mid, S1low) at the sampling timing of the sampling clock signal φ1 are (0, 0, 1). Using a data conversion table, (0, 0, 1) can be converted to “01”.

Similarly, when the data included in the serial data signal is the fourth data DATA4, and this is input to the first data reception sampler SM1high, the second data reception sampler SM1mid, and the third data reception sampler SM1low, the outputs of the first, second, and third samplers (S1high, S1mid, S1low) at the sampling timing of the sampling clock signal φl are (0, 0, 0). Using a data conversion table, (0, 0, 0) can be converted to “00”.

As described above, using a multi-level sampler, the signal levels of PAM4 can be separated and distinguished, and deserialized. Synchronization circuits can be provided downstream of multiple multi-level samplers in the same manner as described above. Note that it is not necessary to use the output signals of all samplers to obtain an eye diagram.

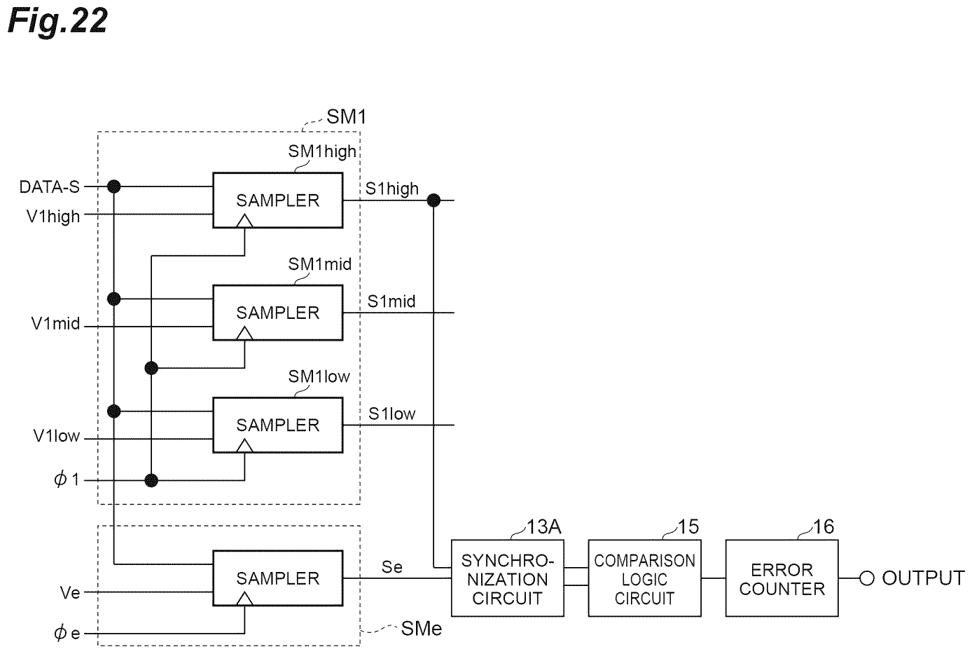

FIG. 22 is a block diagram showing the structure of the multi-level sampler and subsequent circuits.

The structure of the data reception sampler SMI is as shown in FIG. 20. The first output signal S1high of the first data reception sampler SM1high and the reference signal Se of the reference sampler SMe are input to the first synchronization circuit 13A. The structure of the reference sampler SMe is the same as that shown in FIG. 3, and the subsequent circuits and remaining circuits can be the same as those described above. In other words, the receiving device includes the comparison logic circuit 15 and the error counter 16. The reference sampler SMe receives the serial data signal and the reference threshold voltage Ve, and sampling is performed with the sampling clock signal φe. This reference threshold voltage Ve is variable and only one is needed. In this example, an eye diagram can be obtained in the same manner as described above.

In the case of PAM4 signal transmission, it is possible to perform more precise signal quality measurement by using all the sampler outputs with three threshold levels, but even when using only one threshold level output, the signal quality can be evaluated. In this case, the circuit configuration is simplified. The figure shows an example using the high-level threshold voltage V1high as one threshold level, but examples using the mid-level threshold voltage V1mid or the low-level threshold voltage V1low are also possible.

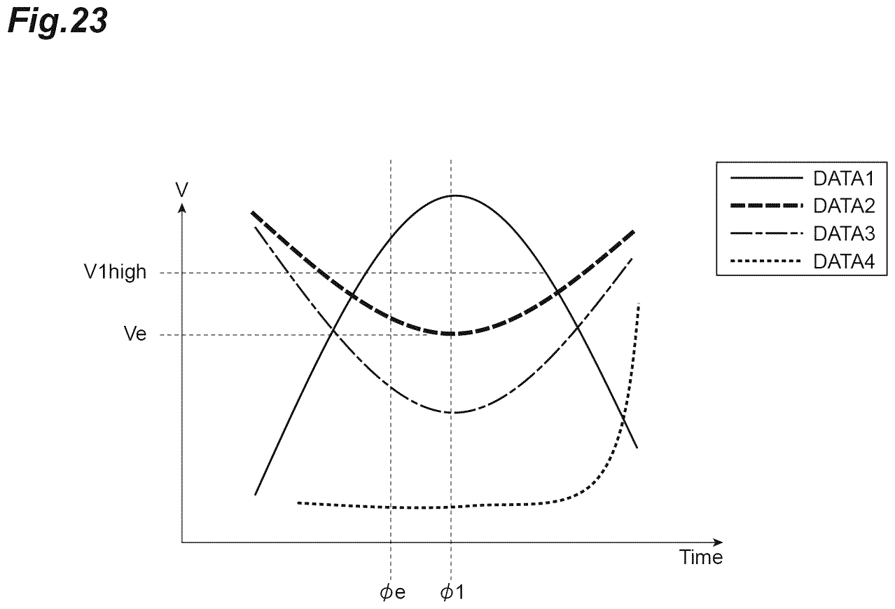

FIG. 23 is a graph showing the change in input voltage (V) to the first data reception sampler SM1high and the reference sampler SMe over time (Time).

When the data included in the serial data signal is the first data DATA1, and this is input to the first data reception sampler SM1high, the output signal S1high of the first data reception sampler SM1high at the timing of the sampling clock signal φ1 is “1”. When the first data DATA1 is input to the reference sampler SMe, the reference signal Se output from the reference sampler SMe at the sampling timing of the sampling clock signal φe is “1”.

Similarly, when the data included in the serial data signal is the second data DATA2, and this is input to the first data reception sampler SM1high, the output signal S1high of the first data reception sampler SM1high at the timing of the sampling clock signal φ1 is “0”. When the second data DATA2 is input to the reference sampler SMe, the reference signal Se output from the reference sampler SMe at the sampling timing of the sampling clock signal φe is “1”.

Similarly, when the data included in the serial data signal is the third data DATA3 or the fourth data DATA4, and this is input to the first data reception sampler SM1high, the output signal S1high of the first data reception sampler SM1high at the timing of the sampling clock signal φ1 is “0”. When the third data DATA3 or the fourth data DATA4 is input to the reference sampler SMe, the reference signal Se output from the reference sampler SMe at the sampling timing of the sampling clock signal φe is “0”.

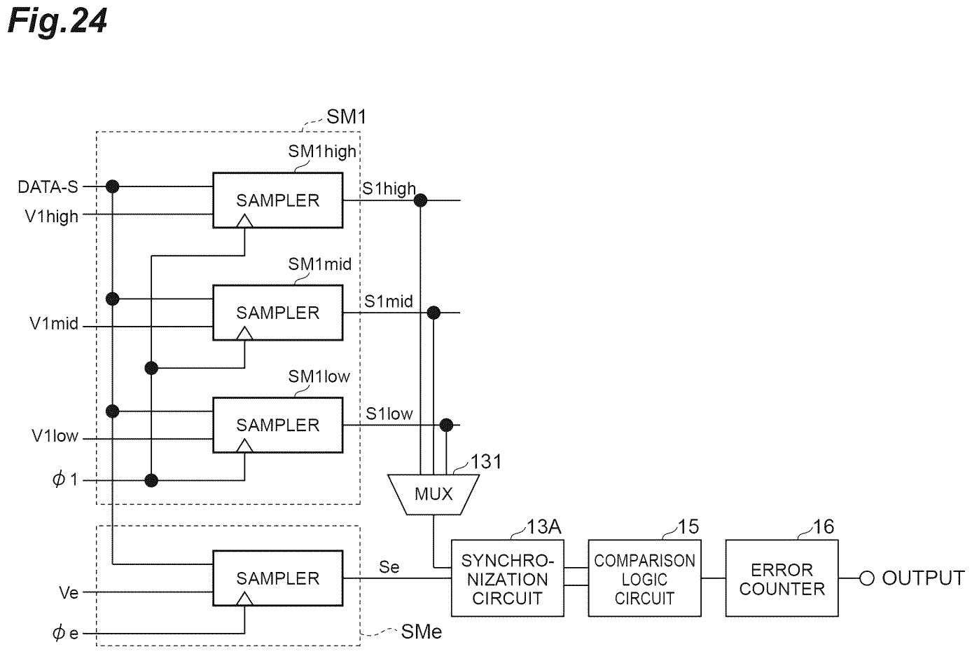

FIG. 24 is a block diagram showing the structure of the multi-level sampler and subsequent circuits.

The circuit shown in FIG. 24 differs from the circuit shown in FIG. 22 in that a multiplexer 131 (selection circuit) is placed on the input side of the first synchronization circuit 13A, and the other structures are the same. The multiplexer 131 receives multiple output signals from the first data reception sampler SM1high. These output signals are the first output signal Sthigh determined by the high-level threshold voltage, the second output signal Simid determined by the mid-level threshold voltage, and the third output signal S1low determined by the low-level threshold voltage. These output signals (S1high, S1mid, S1low) are input to the multiplexer 131, and one is selected and output. The output signal selected by the multiplexer 131 is input to the first synchronization circuit 13A. By switching the signal selected by the multiplexer 131, three eye diagrams determined by the three threshold levels can be obtained. Note that the selection signal for switching the output signals (S1high, S1mid, S1low) can be input to the multiplexer 131 from the control circuit or an external device. In the circuit of this example, since the input signal from the sampler to the first synchronization circuit 13A is switched, the circuit size can be made relatively small. The remaining circuit structure is the same as that shown in FIG. 22.

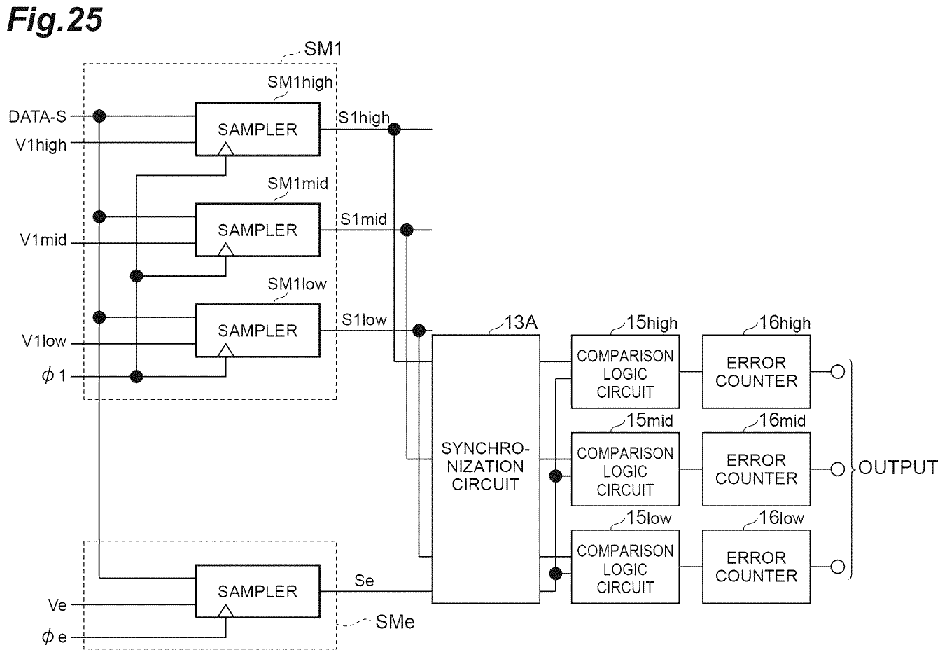

FIG. 25 is a block diagram showing the structure of the multi-level sampler and subsequent circuits.

The circuit shown in FIG. 25 omits the multiplexer shown in FIG. 24 and has a circuit configuration that processes all the output signals (S1high, S1mid, S1low) of the first sampler in parallel without switching by the multiplexer. All the output signals (first output signal S1high, second output signal S1mid, third output signal Slow) from the first sampler are input to the first synchronization circuit 13A.

The first synchronization circuit 13A receives the first output signal S1high, the second output signal S1mid, the third output signal S1low, and the reference signal Se output from the reference sampler SMe. The first synchronization circuit 13A synchronizes and outputs these input signals. The comparison logic circuit 15 described above consists of multiple sub-comparison logic circuits.

The first output signal S1high is input to one input terminal of the first comparison logic circuit 15high. The second output signal S1mid is input to one input terminal of the second comparison logic circuit 15mid. The third output signal S1low is input to one input terminal of the third comparison logic circuit 15low. The reference signal Se is input to the other input terminal of each comparison logic circuit. Each comparison logic circuit is preferably an XOR gate, as shown in FIG. 2, and outputs “0” if the logic of the input data matches and “1” if it differs.

The output terminal of the first comparison logic circuit 15high is connected to the input terminal of the first error counter 16high. The output terminal of the second comparison logic circuit 15mid is connected to the input terminal of the second error counter 16mid. The output terminal of the third comparison logic circuit 15low is connected to the input terminal of the third error counter 16low. The processing in each error counter is the same as that shown in FIG. 2. According to this circuit, since parallel processing is performed for the outputs of the three samplers, a multi-level eye diagram can be obtained in a short time.

As described above, in the receiving signal quality monitor shown in FIGS. 20 to 25, the serial data signal is a pulse amplitude modulation (PAM) signal having k levels, where k is an integer and satisfies 3≤k, and each of the plurality of data reception samplers comprises (k−1) samplers. Each of (k−1) samplers, along with the serial data signal, receives a threshold voltage (V1high, V1mid, V1low) at a different level, so that (k−1) comparison results are output from the (k−1) samplers. Each of the (k−1) samplers outputs (k−1) comparison results (S1high, S1mid, S1low). This configuration allows the processing of multi-level serial data signals.

In the receiving signal quality monitor shown in FIG. 25, one sampler included in the plurality of data reception samplers outputs (k−1) comparison results (S1high, S1mid, S1low) as the first output signal, and the first synchronization circuit 13A receives the (k−1) comparison results and the second output signal (reference signal Se) of the reference sampler. The comparison logic circuit 15 includes (k−1) sub-comparison logic circuits (15high, 15mid, 15low), and each of the (k−1) sub-comparison logic circuits receives the (k−1) comparison results (S1high, S1mid, S1low) synchronously output from the first synchronization circuit 13A and the second output signal (reference signal Se).

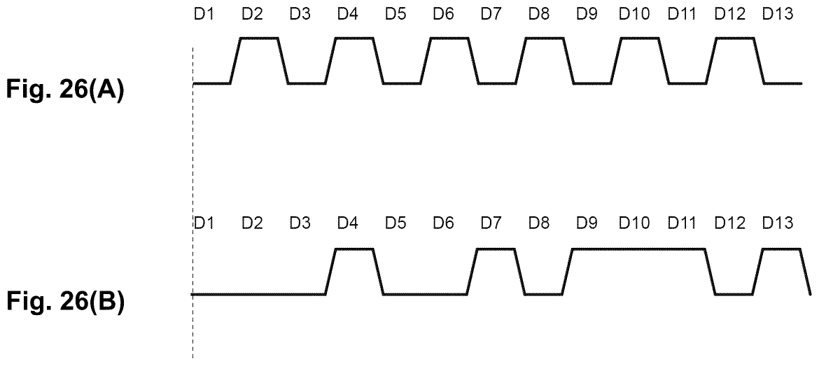

FIGS. 26(A) and 26(B) are timing charts of exemplary serial data signals.

The serial data signal in FIG. 26(A) is a periodic signal. The serial data signal in FIG. 26(B) is a signal with a random pattern or a pseudo-random pattern. In the case of ⅕ rate transmission, when data sampling for the eye diagram is performed, data sampling is performed every 5 data, and the data is superimposed at the center of the eye diagram. In other words, in either signal, after sampling the data D1, the data D6 is sampled.

The size of the eye opening of the eye diagram obtained from the periodic serial data signal (FIG. 26(A)) is generally larger than the size of the eye opening of the eye diagram obtained from the serial data signal with a random pattern (FIG. 26(B)). Since it is preferable to evaluate the transmission line characteristics assuming all inputs, when accurately evaluating the quality of the received signal, it is preferable that the serial data signal received has a random pattern or a pseudo-random pattern.

As described above, the receiving signal quality monitor described above includes a plurality of data reception samplers SMI to SMm, each receiving the serial data signal DATA-S, connected in parallel, and each input terminal of the sampling clock signal on (1≤n≤m, m and n are integers) is input with each clock signal included in the multi-phase clock signal. The receiving signal quality monitor includes a reference sampler SMe that receives the serial data signal, one or more input terminals that receive one or more clock signals included in the multi-phase clock signal, and an output terminal connected to the input terminal of the sampling clock signal ve of the reference sampler. The receiving signal quality monitor includes a phase adjustment circuit 11 capable of sweeping the phase of the sampling clock signal ve output within a phase range of N times (2≤N) the unit interval (UI) of the serial data signal. The receiving signal quality monitor includes a first synchronization circuit 13A that receives the first output signal of one sampler included in the plurality of data reception samplers and the second output signal of the reference sampler SMe, synchronizes and outputs the first and second output signals; and a comparison logic circuit 15 that receives the first and second output signals synchronously output from the first synchronization circuit 13A. The comparison logic circuit 15 receives the first and second output signals synchronously output from the first synchronization circuit 13A, and the comparison logic circuit 15 outputs a comparison result related to the quality of the received signal.

In the receiving device described above, the frequency of the sampling clock signal on is preferably 1/N (2≤N) of the frequency of the serial data signal DATA-S. The receiving signal quality monitor includes a phase adjustment circuit 11 capable of sweeping the phase of the sampling clock signal pe output within a phase range of N times (2≤N) the unit interval (UI) of the serial data signal (within a multiple phase range). The phase of the sampling clock signal pe can be swept within a multiple phase range of the unit interval (UI). Preferably, when the frequency of the sampling clock signal on received is 1/N (e.g., N=5) of the frequency given by the reciprocal of the time width of one data of the input serial data signal, the sweepable phase range is N×UI (e.g., N=5 (phase sweep range 360°)). This phase range, for example, even if it is (N/2)×UI or more (e.g., 2.5 UI), has the effect of reducing the impact of setup violations and hold violations. Also, the phase range (phase variation range R (Pφe)) adjusted by the phase adjustment circuit 11 is preferably at least one cycle (N×UI in the example of FIG. 15) of the sampling clock signal φe input to the reference sampler, and by expanding the phase range, it becomes easier to capture the eye opening position even if it shifts.

In the receiving device described above, the phase adjustment circuit 11 is placed in front of the reference sampler SMe, but no phase adjustment circuit for delay adjustment is placed in front of the other samplers. Compared to a receiving device that requires such a phase adjustment circuit for delay adjustment, the receiving device described above can reduce circuit area and power consumption. Also, by setting the phase sweep range as described above, if no delay adjustment circuit is placed in front of each sampler, the impact of the inherent delay of such a delay adjustment circuit can be suppressed. Also, even if unintended inherent delay occurs due to changes in the operating environment in the phase adjustment circuit 11, the phase sweep range is wide as described above, so an eye diagram can be obtained.

Thus, the phase adjustment circuit technology for eye monitors in data reception devices using multi-phase clock signals has been disclosed. In this technology, preferably, the input data is set to a random pattern. The phase adjustment range by the phase adjustment circuit is set wide. Also, in the comparison logic circuit, synchronization is taken so as not to cause synchronization errors in the part related to the eye opening of the eye diagram. As a result, it is not necessary to add dummy circuits or phase compensation circuits of the phase adjustment circuit in the path of the multi-phase clock signal to cancel the inherent delay of the phase adjustment circuit, and power consumption and area can be reduced.

Supplementary explanation on signal quality evaluation. The signal received via the transmission line is degraded by the load each has. The quality of the transmission signal can be judged by looking at the eye opening degree of the eye diagram. The eye diagram is obtained by superimposing the signal with two minimum units of transmission data as one cycle, and the eye opening degree refers to the size of the opening at the center of the eye diagram. The larger the height and width of the opening, the better the signal quality is evaluated. Note that the signal quality can also be evaluated by evaluating only a part of the quality monitor signal instead of the entire eye opening. Only the vertical opening dimension passing through the center of the eye opening is evaluated. Only the horizontal opening dimension passing through the center of the eye opening is evaluated. The opening dimension passing through an appropriate position of the eye opening is evaluated. The opening dimension in the diagonal direction of the eye opening is evaluated. Various evaluation methods can be considered.

In recent years, with the spread of communication devices, paperless operations, and the spread of telework, the data rate of communication data required has been increasing. The receiving device described above supports high data rate communication because it performs data transmission using multi-phase clocks (m-phase clocks). The receiving device described above has low power consumption and a small area. The larger the Nin 1/N rate transmission, the greater this effect, but in the device described above, appropriate synchronization can also be performed.

### REFERENCE SIGNS LIST

11 . . . phase adjustment circuit, 11A . . . multiplexer, 11B . . . phase interpolator, 11C . . . multiplexer, 12 . . . voltage generator, 13A . . . first synchronization circuit, 13B . . . second synchronization circuit, 13DIV . . . frequency divider, 15 . . . comparison logic circuit, 16 . . . error counter, 17 . . . CDR circuit, 18 . . . control circuit, 72 . . . phase difference detector, 73 . . . filter, 74 . . . voltage-controlled oscillator, 101 . . . amplifier, 110 . . . input section, 131 . . . multiplexer, 172 . . . phase difference detector, 173 . . . filter, 174 . . . voltage-controlled oscillator, 175 . . . multi-phase clock signal generator, display, CB . . . communication cable, COMP . . . comparator, OUTPUT . . . quality monitor signal, SM1 to SMm . . . data reception sampler, SMe . . . reference sampler.

1. A receiving signal quality monitor, comprising:
a plurality of data reception samplers connected in parallel, each receiving a serial data signal and being input with a sampling clock signal, resulting in multi-phase sampling clock signals being input to the data reception samplers;
a reference sampler configured to receive the serial data signal;
a phase adjustment circuit configured to allow a phase of a sampling clock signal input to the reference sampler to be swept within a phase range corresponding to N times a unit interval (UI) of the serial data signal, where 2≤N;
a first synchronization circuit to which an output signal of one of the plurality of data reception samplers and an output signal of the reference sampler are input; and
a comparison logic circuit to which two output signals synchronously output from the first synchronization circuit are input.

2. The receiving signal quality monitor according to claim 1,
wherein a phase range adjusted by the phase adjustment circuit is at least one cycle of the sampling clock signal input to the reference sampler.

3. The receiving signal quality monitor according to claim 1,
further comprising a counter configured to count an output result of the comparison logic circuit.

4. The receiving signal quality monitor according to claim 1,
wherein the reference sampler comprises:
a first input terminal that receives the serial data signal; and
a second input terminal that receives a variable reference threshold voltage, and
wherein the reference sampler is configured to sample, in synchronization with the sampling clock signal whose phase can be swept, a comparison result between the serial data signal and the reference threshold voltage.

5. The receiving signal quality monitor according to claim 4,
wherein each sampler in the plurality of data reception samplers comprises:
a first input terminal that receives the serial data signal; and
a second input terminal that receives a threshold voltage, and
wherein each sampler in the plurality of data reception samplers is configured to sample, in synchronization with the sampling clock signal corresponding to the sampler, included in the multi-phase sampling clock signals, a comparison result between the serial data signal and the threshold voltage.

6. The receiving signal quality monitor according to claim 1, further comprising:
a second synchronization circuit configured to receive a plurality of output signals output from the plurality of data reception samplers; and
a CDR circuit that receives the plurality of output signals output from the second synchronization circuit and generates the multi-phase sampling clock signals.

7. The receiving signal quality monitor according to claim 1,
wherein the serial data signal is a pulse amplitude modulation (PAM) signal having k levels, where k is an integer and satisfies 3≤k, and
wherein each of the plurality of data reception samplers comprises (k−1) samplers, each configured to receive a threshold voltage at a different level, along with the serial data signal so that (k−1) comparison results are output from the (k−1) samplers.

8. The receiving signal quality monitor according to claim 7,
wherein (k−1) comparison results are output from one sampler in the plurality of data reception samplers;
wherein the (k−1) comparison results and an output signal of the reference sampler are input to the first synchronization circuit;
wherein the comparison logic circuit comprises (k−1) sub-comparison logic circuits; and
wherein each of the (k−1) sub-comparison logic circuits is configured to receive an output signal synchronously output from the first synchronization circuit.

9. The receiving signal quality monitor according to claim 6, wherein the phase adjustment circuit comprises:
a selection circuit to which the multi-phase sampling clock signals output from the CDR circuit is input; and
a phase interpolator configured to receives an output signal of the selection circuit.
